(19) United States
(12) Patent Application Publication
(10) Pub. No.: US 2026/0288207 A1
(43) Pub. Date: Sep. 24, 2026

(54) WINDOW, ELECTRONIC DEVICE INCLUDING THE SAME, AND MANUFACTURING METHOD FOR THE SAME

(71) Applicant: Samsung Display Co., Ltd., Yongin-si (KR)

(72) Inventors: RANGKYUN MOK, Yongin-si (KR); TAEHO LEE, Yongin-si (KR)

(21) Appl. No.: 19/571,619

(22) Filed: Mar. 19, 2026

(30) Foreign Application Priority Data
Mar. 19, 2025 (KR) 10-2025-0035589

(51) Int. Cl. G06F 1/16; C03C 17/30

(52) U.S. Cl. CPC G06F 1/1656; C03C 17/30; G06F 1/1618; G06F 1/1641; C03C 2218/32

(57) ABSTRACT

A window including a first non-folding portion, a second non-folding portion, and a folding portion disposed between the first non-folding portion and the second non-folding portion, the window includes a base layer and a resin layer disposed on the base layer. The resin layer includes a polymer compound derived from a resin composition that includes a siloxane oligomer and a first organic compound represented by Formula 1 as described herein.

### CROSS-REFERENCE TO RELATED APPLICATIONS

This U.S. non-provisional patent application claims priority under 35 U.S.C. § 119 of Korean Patent Application No. 10-2025-0035589, filed on Mar. 19, 2025, the entire contents of which are hereby incorporated by reference.

The present disclosure relates to a window, an electronic device including the window, and a method for manufacturing the window.

### BACKGROUND

Various types of electronic devices are being used to provide information through images on a screen. Electronic devices that include flexible display devices that are foldable or bendable are being developed. The flexible display devices, unlike rigid display devices, are variously modifiable in shape by being foldable, rollable, or bendable, and thus are portable without the need to limit the display screen sizes.

Such a flexible display device requires a window to protect a display panel without prohibiting the folding or bending capabilities. There remains a need for developing a window having satisfactory folding characteristics, excellent optical properties, and mechanical properties.

### SUMMARY

The present disclosure provides a window having excellent self-restoring characteristics, excellent optical properties, and excellent mechanical durability together.

The present disclosure provides an electronic device including a window having excellent self-restoring characteristics, excellent optical properties, and excellent mechanical durability together.

The disclosure an embodiment that includes a window comprising a first non-folding portion, a second non-folding portion, and a folding portion disposed between the first non-folding portion and the second non-folding portion. The window includes a base layer and a resin layer disposed on the base layer. The resin layer includes a polymer compound derived from a resin composition including a siloxane oligomer and a first organic compound represented by Formula 1.

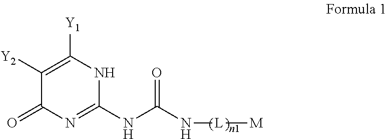

In Formula 1, Y₁ and Y₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, M is a substituted or unsubstituted (meth)acrylate group, a substituted or unsubstituted vinyl group, a substituted or unsubstituted epoxy group, or a substituted or unsubstituted oxetanyl group, each L is independently a direct linkage, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and n1 is an integer of 1 to 20.

In an embodiment, the siloxane oligomer may include a silsesquioxane compound having at least one polymerizable functional group.

In an embodiment, the siloxane oligomer may include a silsesquioxane compound having at least one (meth)acrylate group.

In an embodiment, the resin composition may further include a second organic compound different from the first organic compound, and the second organic compound may include a polymerizable monomer.

In an embodiment, the second organic compound may be represented by Formula 2.

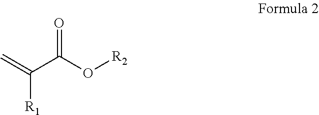

In Formula 2, R₁ may be a hydrogen atom or a substituted or unsubstituted alkyl group having 1 to 20 carbon atoms, and R₂ may be a substituted or unsubstituted alkyl group having 1 to 20 carbon atoms.

In an embodiment, the polymer compound may be formed through a polymerization reaction of the siloxane oligomer, the first organic compound, and the second organic compound.

In an embodiment, the polymer compound may include a plurality of cores including the siloxane oligomer, and a plurality of linkages disposed between the plurality of cores connect the plurality of cores, the plurality of linkages may include the first organic compound, and adjacent linkages of the plurality of linkages may be connected through hydrogen bonds.

In an embodiment, the resin layer may have a transmittance of about 90% or greater for light having a central wavelength of about 400 nm to about 700 nm.

In an embodiment, the resin layer may have a yellow index of about 2 or less.

In an embodiment, the folding portion of the base layer comprises a concave portion, and the resin layer is disposed within the concave portion.

In an embodiment, the resin layer may fill the concave portion and overlap the first non-folding portion, the second non-folding portion, and the folding portion.

In an embodiment, the base layer may be a glass substrate.

In an embodiment of the disclosure, an electronic device includes a display module including a folding display portion that is foldable with respect to a folding axis extending in one direction, and a first non-folding display portion and a second non-folding display portion that are spaced apart with the folding display portion therebetween, and a window disposed on the display module and including a folding portion corresponding to the folding display portion, and a first non-folding portion and a second non-folding portion respectively corresponding to the first non-folding display portion and the second non-folding display portion, wherein the window includes a base layer, and a resin layer disposed on the base layer and including a polymer compound derived from a resin composition including a siloxane oligomer and a first organic compound represented by Formula 1.

In an embodiment, the folding portion of the base layer comprises a concave portion, and the resin layer is disposed within the concave portion.

In an embodiment, the base layer may include a first base surface in which the concave portion is defined, and a second base surface facing the first base surface, and the first base surface may be disposed adjacent to the display module.

In an embodiment, the base layer may include a first base surface in which the concave portion is defined, and a second base surface facing the first base surface, and the second base surface may be disposed adjacent to the display module.

In an embodiment, the electronic device may further include at least one of a power module, a processor, or a memory.

In an embodiment of the disclosure, a method for manufacturing a window includes preparing a base layer including a folding region, and a first non-folding region and a second non-folding region that are spaced apart with the folding region therebetween, applying a resin composition including a siloxane oligomer and a first organic compound represented by Formula 1 onto one surface of the base layer to form a preliminary resin layer, and providing heat or light to the preliminary resin layer to form a resin layer.

In an embodiment, the folding portion of the base layer comprises a concave portion, and the resin layer is disposed within the concave portion. The resin layer may be provided to fill the concave portion.

In an embodiment, providing heat or ultraviolet light to the preliminary resin layer may include polymerizing the siloxane oligomer with the first organic compound.

### BRIEF DESCRIPTION OF THE FIGURES

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a block diagram of an electronic device according to an embodiment of the disclosure;

FIG. 2 shows schematic views of an electronic device according to an embodiment of the disclosure;

FIG. 3A is a perspective view showing a state in which an electronic device according to an embodiment of the disclosure is unfolded;

FIG. 3B is a perspective view showing an inner-folding process of the electronic device shown in FIG. 3A;

FIG. 3C is a perspective view showing an outer-folding process of the electronic device shown in FIG. 3A;

FIG. 4A is a perspective view showing a state in which an electronic device according to an embodiment of the disclosure is unfolded;

FIG. 4B is a perspective view showing an inner-folding process of the electronic device shown in FIG. 4A;

FIG. 4C is a perspective view showing an outer-folding process of the electronic device shown in FIG. 4A;

FIG. 5 is an exploded perspective view of an electronic device according to an embodiment of the disclosure;

FIG. 6 is a cross-sectional view of an electronic device according to an embodiment of the disclosure;

FIGS. 7A and 7B are each views schematically showing a cross-section of a display device according to an embodiment in a folded state;

FIG. 8A is a cross-sectional view showing a window according to an embodiment of the disclosure;

FIG. 8B is a cross-sectional view showing a portion of a window according to an embodiment of the disclosure;

FIG. 9A schematically shows a polymer compound included in a resin layer according to an embodiment of the disclosure;

FIG. 9B is a view enlarging a portion of the polymer compound included in a resin layer shown in FIG. 9A;

FIGS. 10A and 10B are each views schematically showing a cross-section of one component included in an electronic device according to an embodiment;

FIG. 11 is a flowchart showing a method for manufacturing a window according to an embodiment of the disclosure; and

FIGS. 12A to 12F are views showing some processes in a method for manufacturing a window according to an embodiment of the disclosure.

### DETAILED DESCRIPTION

Hereinafter, embodiments of the disclosure are described with reference to the drawings.

In this specification, it will be understood that when an element (or a region, a layer, a portion, or the like) is referred to as being “on”, “connected to” or “coupled to” another element, it may be directly connected to or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element could be termed a second element without departing from the scope of the disclosure. Similarly, a second element could be termed a first element. The singular expressions “a”, “an” and “the” are intended to include the plural forms as well, unless the context clearly indicates otherwise.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

As used herein, being “disposed directly on” may indicate that there is no additional layer, film, region, plate, or the like between a part and another part such as a layer, a film, a region, a plate, or the like. For example, being “disposed directly on” may indicate that two layers or two members are disposed without an additional member, such as an adhesive member, therebetween.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “substituted or unsubstituted” may indicate that one is substituted or unsubstituted with at least one substituent selected from the group consisting of a deuterium atom, a halogen atom, a cyano group, a nitro group, an amine group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents presented as a previous example may be substituted or unsubstituted. For example, a biphenyl group may be interpreted as an aryl group or as a phenyl group substituted with a phenyl group.

As used herein, examples of a halogen atom may include a fluorine atom, a chlorine atom, a bromine atom, and an iodine atom.

As used herein, an alkyl group may be linear or branched. The number of carbon atoms in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but are not limited thereto.

As used herein, an alkenyl group indicates a hydrocarbon group including at least one carbon double bond in the middle or end of an alkyl group having 2 or more carbon atoms. The alkenyl group may be linear or branched. The number of carbon atoms is not particularly limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and the like, but are not limited thereto.

As used herein, an aryl group indicates any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and the like, but are not limited thereto.

As used herein, a heteroaryl group may include at least one of B, O, N, P, Si, or S as a hetero atom. When the heteroaryl group contains two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and the like, but are not limited thereto.

As used herein, a direct linkage may indicate a single bond.

As used herein, a “monomeric body” is synonymous with a “monomer”. As used herein, the monomer is distinguished from an oligomer and a polymer by weight average molecular weight. A monomer is a single compound that may be polymerized. The term “oligomer” indicates a compound having a weight average molecular weight of about 1,000 g/mol or less. The term “polymer” indicates a compound having a weight average molecular weight of greater the 1000 g/mol. As used herein, “polymerizable functional group” may indicate a group involved in a polymerization reaction, such as a carbon-carbon double bond, such as a vinyl group, a (meth)acrylate group, an epoxy group, and an oxetanyl group.

As used herein, the term “(meth)acrylate” indicates acrylate and methacrylate, “(meth)acryl” indicates acryl and methacryl, and “(meth)acryloyl” indicates acryloyl and methacryloyl.

Hereinafter, a window according to an embodiment of the disclosure and an electronic device according to an embodiment are described with reference to the drawings.

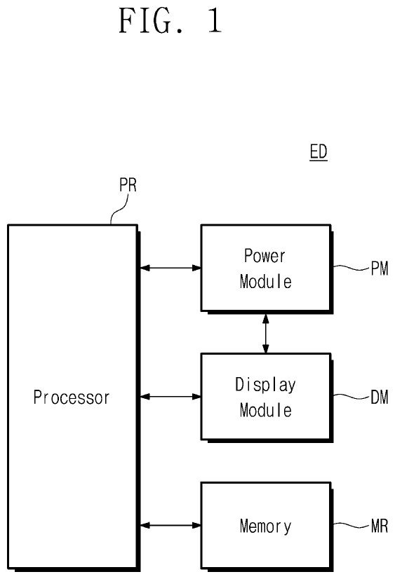

FIG. 1 is a block diagram of an electronic device according to an embodiment. Referring to FIG. 1, an electronic device ED according to an embodiment may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information required for the operation of the processor PR or the display module DM. When the processor PR executes an application stored in the memory MR, image data signals and/or input control signals are transmitted to the display module DM, and the display module DM may process the received signal and output image information through a display screen. The display module DM may include a display panel that displays an image.

The power module PM may include a power supply module such as a power adapter or a battery device, and a power conversion module that converts power supplied by the power supply module to generate power required for the operation of the electronic device ED.

At least one of the components of the electronic device ED previously described may be included in a display module according to an embodiment, which will be described later, and a display device according to an embodiment including the same. In addition, some of the individual modules functionally included in one module may be included in the display device, and others may be separately provided from the display device. For example, the display device may include a display module DM, and the processor PR, the memory MR, and the power module PM may be provided in the form of other devices within the electronic device ED, rather than the display device.

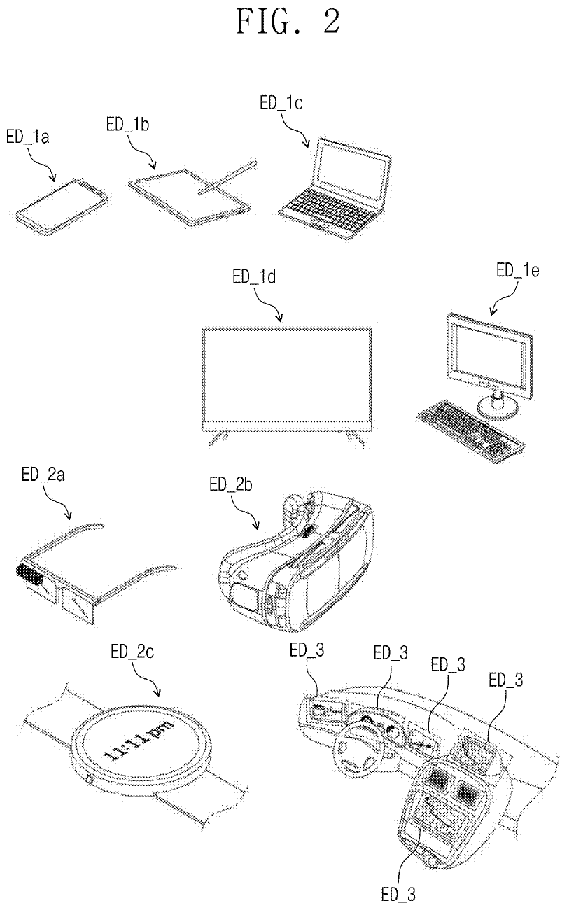

FIG. 2 shows schematic views of embodiments of various electronic devices.

Referring to FIG. 2, various electronic devices including the display module according to an embodiment may include electronic devices for displaying images, such as a smart phone ED_1a, a tablet PC ED_1b, a laptop ED_1c, a TV ED_1d, and a desk monitor ED_1e, wearable electronic devices such as smart glasses ED_2a, a head mounted display ED_2b, and a smart watch ED_2c, and vehicle electronic devices ED_3 such as a center information display (CID) and a room mirror display disposed on an instrument panel, a center fascia, or a dashboard of a vehicle.

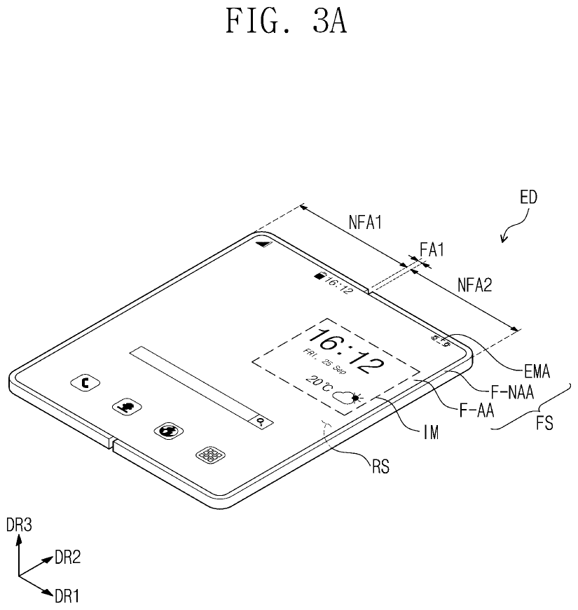

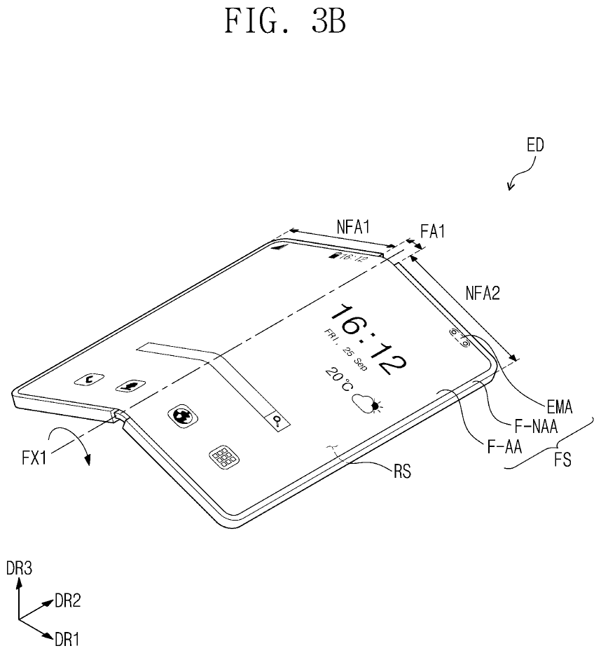

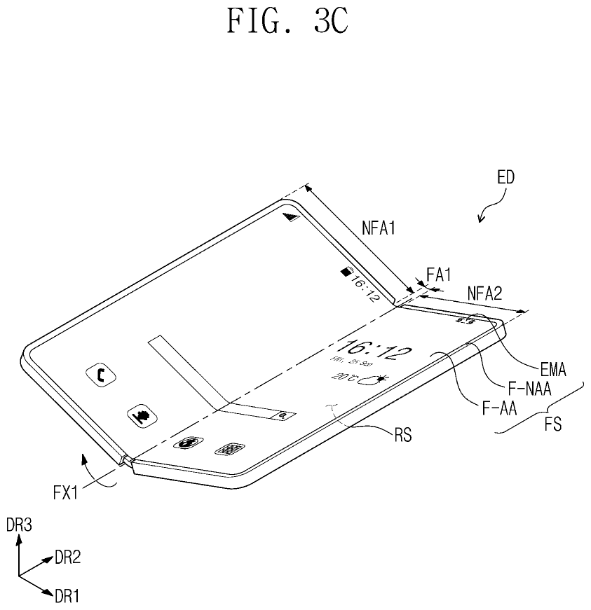

FIGS. 3A to 3C are perspective views of an electronic device ED according to an embodiment of the disclosure. In FIGS. 3A to 3C, as an example, a smartphone is illustrated as the electronic device ED. However, the description of the electronic device ED described with reference to FIGS. 3A to 3C may equally apply to other electronic devices.

FIG. 3A is a perspective view showing a state in which an electronic device according to an embodiment is unfolded. FIG. 3B is a perspective view showing an inner-folding process of the electronic device shown in FIG. 3A. FIG. 3C is a perspective view showing an outer-folding process of the electronic device shown in FIG. 3A.

An electronic device ED according to an embodiment may be a device activated in response to electrical signals. For example, the electronic device ED may be a mobile phone, a tablet, a car navigation system, a game console, or a wearable device, but the embodiment is not limited thereto. In FIG. 3A and the like herein, as an example, a mobile phone is illustrated as the electronic device ED.

Referring to FIGS. 3A to 3C, the electronic device ED according to an embodiment may include a first display surface FS defined by a first direction DR1 and a second direction DR2 crossing the first direction DR1. The electronic device ED may provide an image IM to users through the first display surface FS. The electronic device ED according to an embodiment may display the image IM towards a third direction DR3 on the first display surface FS parallel to each of the first direction DR1 and the second direction DR2. Herein, a front surface (or an upper surface) and a rear surface (or a lower surface) of respective members are defined with respect to a direction in which the image IM is displayed. The front and rear surfaces may oppose each other in the third direction DR3 and a normal direction of each of the front and rear surfaces may be parallel to the third direction DR3.

The electronic device ED according to an embodiment may include the first display surface FS and a second display surface RS. The first display surface FS may include an active region F-AA and a peripheral region F-NAA. The active region F-AA may include an electronic module region EMA. The second display surface RS may be defined as a surface facing at least a portion of the first display surface FS. That is, the second display surface RS may be defined as a portion of the rear surface of the electronic device EA.

The electronic device ED according to an embodiment may detect external inputs applied from the outside. The external inputs may include various forms of inputs provided from outside the electronic device ED. For example, the external inputs may include external inputs applied when approaching the electronic device ED or being adjacent by a certain distance (e.g., hovering), as well through as contact by a part of a body such as a user's hand. In addition, the external inputs may have various forms such as force, pressure, temperature, and light.

FIG. 3A and the following drawings show the first to third directions DR1 to DR3, and directions indicated by the first to third directions DR1, DR2, and DR3 described herein are relative concepts, and may thus be changed to other directions.

The active region F-AA of the electronic device ED may be a region activated in response to electrical signals. The electronic device ED according to an embodiment may display the image IM through the active region F-AA. In addition, the active region F-AA may detect various forms of external inputs. The peripheral region F-NAA is adjacent to the active region F-AA. The peripheral region F-NAA may have a certain color. The peripheral region F-NAA may surround the active region F-AA. Accordingly, the shape of the active region F-AA may be substantially defined by the peripheral region F-NAA. However, this is shown as an example, and the peripheral region F-NAA may be disposed adjacent to only one side of the active region F-AA, or may not be provided. The electronic device ED according to an embodiment of the disclosure may include various forms of active regions and is not limited to any one embodiment.

The electronic device ED may include a folding region FA1 and non-folding regions NFA1 and NFA2. In an embodiment, the non-folding regions NFA1 and NFA2 may be disposed adjacent to the folding region FA1 with the folding region FA1 therebetween. The electronic device ED according to an embodiment may include a first non-folding region NFA1 and a second non-folding region NFA2, which are spaced apart with the folding region FA1 therebetween in the first direction DR1. For example, the first non-folding region NFA1 may be disposed at one side of the folding region FA1 in the first direction DR1, and the second non-folding region NFA2 may be disposed at the other side of the folding region FA1 in the first direction DR1.

FIGS. 3A to 3C show an embodiment of the electronic device ED including one folding region FA1, but the embodiment is not limited thereto, and in the electronic device ED, a plurality of folding regions may be defined. For example, the electronic device according to an embodiment may include two or more folding regions and three or more non-folding regions disposed with each of the folding regions therebetween.

Referring to FIG. 3B, the electronic device ED according to an embodiment may be folded with respect to a first folding axis FX1. The first folding axis FX1 is a virtual axis extending in a direction of the second direction DR2, and the first folding axis FX1 may be parallel to a long side direction of the electronic device ED. The first folding axis FX1 may extend along the second direction DR2 on the first display surface FS.

The electronic device ED may be folded with respect to the first folding axis FX1 to become in-folded such that one region overlapping the first non-folding region NFA1 and the other region overlapping the second non-folding region NFA2 on the first display surface FS face each other.

In the electronic device ED according to an embodiment, the second display surface RS may be viewed in an in-folded state by users. The second display surface RS may further include an electronic module region in which an electronic module including various components is disposed, and is not limited to any one embodiment.

Referring to FIG. 3C, the electronic device ED may be folded with respect to the first folding axis FX1 to become out-folded such that one region overlapping the first non-folding region NFA1 and the other region overlapping the second non-folding region NFA2 on the second display surface RS face each other.

However, the embodiment is not limited thereto, and the electronic device ED may be folded with respect to a plurality of folding axes such that portions of each of the first display surface FS and the second display surface RS may face each other, and the number of folding axes and the number of the corresponding non-folding regions are not particularly limited.

The electronic module region EMA may have various electronic modules disposed therein. For example, the electronic module may include at least any one of a camera, a speaker, a light detection sensor, or a heat detection sensor. The electronic module region EMA may detect an external subject received through the first and second display surfaces FS and RS, or provide sound signals such as voice to the outside through the first and second display surfaces FS and RS. The electronic modules may include a plurality of components, and are not limited to any one embodiment.

The electronic module region EMA may be surrounded by the active region F-AA and the peripheral region F-NAA. However, the embodiment of the disclosure is not limited thereto, and the electronic module region EMA may be disposed in the active region F-AA, but is not limited to any one embodiment.

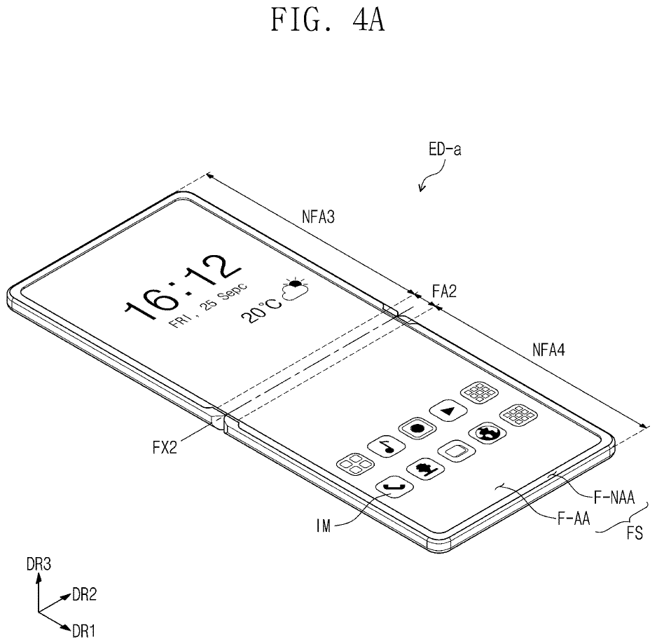

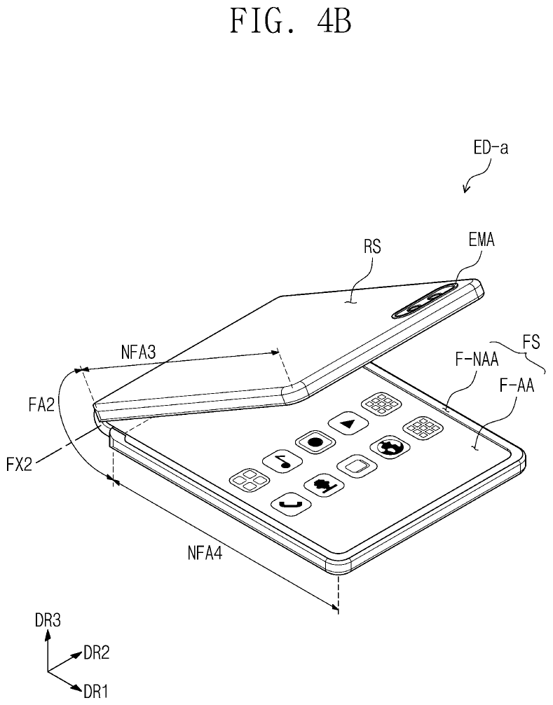

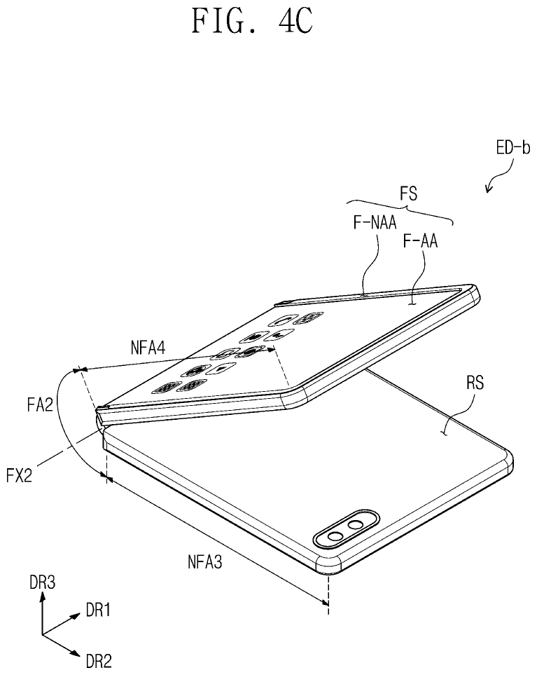

FIG. 4A is a perspective view showing a state in which an electronic device according to an embodiment is unfolded. FIG. 4B is a perspective view showing an inner-folding process of the electronic device shown in FIG. 4A. FIG. 4C is a perspective view showing an outer-folding process of the electronic device shown in FIG. 4A.

An electronic device ED-a according to an embodiment may be folded with respect to a second folding axis FX2 extending in one direction parallel to the second direction DR2. FIG. 4B shows a case in which a direction that the second folding axis FX2 extends is parallel to a direction that a short side of the electronic device ED-a extends. However, the embodiment is not limited thereto.

The electronic device ED-a according to an embodiment may include at least one folding region FA2 and non-folding regions NFA3 and NFA4 adjacent to the folding region FA2. The non-folding regions NFA3 and NFA4 may be spaced apart with the folding region FA2 therebetween.

The folding region FA2 has a certain curvature and a certain radius of curvature. In an embodiment, the first non-folding region NFA3 and the second non-folding region NFA4 may face each other, and the electronic device ED-a may be inner-folded such that the display surface FS is not exposed to the outside. In addition, referring to FIG. 4C, in an embodiment, the electronic device ED-a may be outer-folded such that the first display surface FS is exposed to the outside.

The electronic device ED-a according to an embodiment may include a second display surface RS, and the second display surface RS may be defined as a surface facing at least a portion of the first display surface FS. The second display surface RS may include an electronic module region EMA in which electronic modules including various components are disposed. In addition, images or videos may be displayed on at least a portion of the second display surface RS.

In an embodiment, when the electronic device ED-a is in an unfolded state, the first display surface FS may be viewed by users and when the electronic device ED-a is in an inner-folded state, the second display surface RS may be viewed by users.

In an embodiment, the electronic devices ED and ED-a may be configured such that an inner-folding operation or an outer-folding operation is mutually repeated from an unfolding operation, but the embodiment is not limited thereto. In an embodiment, the electronic devices ED and ED-a may be configured to select any one of an unfolding operation, an inner-folding operation, or an outer-folding operation. In addition, when a plurality of folding regions is included, a folding direction of at least one of the plurality of folding regions may be different from a folding direction of the other folding regions. For example, when two folding regions are included, two non-folding regions with one folding region therebetween are folded by an inner-folding operation, and the two non-folding regions with the other folding region therebetween may be folded by an outer-folding operation.

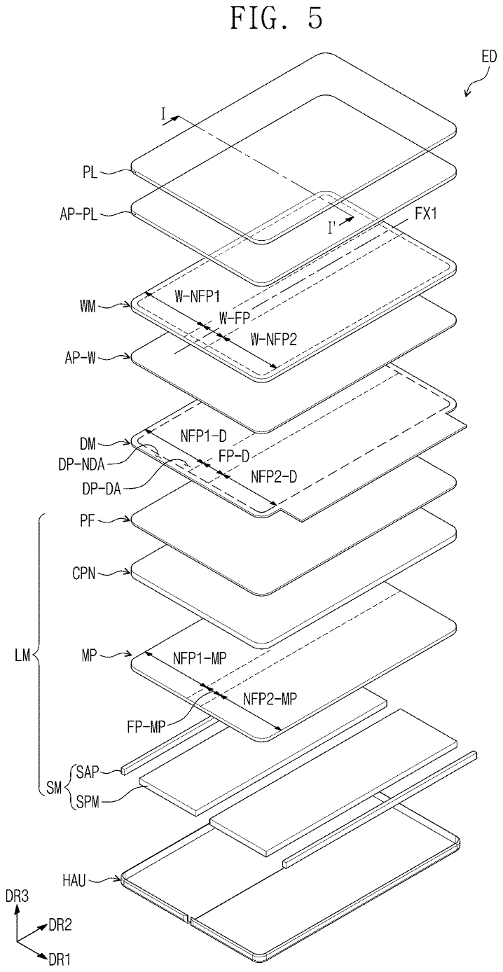

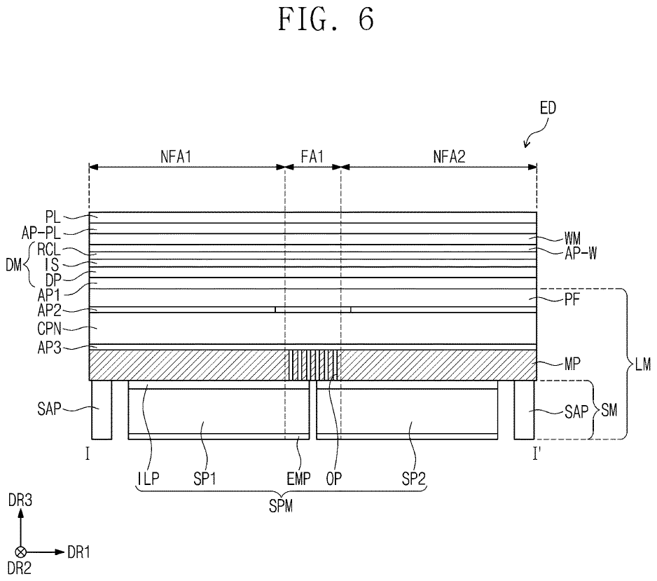

FIG. 5 is an exploded perspective view of an electronic device according to an embodiment, and FIG. 6 is a cross-sectional view of an electronic device according to an embodiment. FIG. 5 shows an exploded perspective view of an electronic device according to an embodiment shown in FIG. 3A as an example. FIG. 6 is a cross-sectional view showing a portion corresponding to line I-I′ of FIG. 5.

FIGS. 5 and 6, and the like show a case in which a folding axis FX1 of the electronic device ED shown in FIG. 3A and the like is parallel to a long side of the electronic device ED, but the embodiment is not limited thereto, and descriptions with reference to the other drawings may also apply to a case in which a folding axis FX2 is parallel to a short side of the electronic device as shown in FIG. 4A and the like.

Referring to FIGS. 5 and 6, the electronic device ED according to an embodiment may include a display module DM and a window WM disposed above the display module DM. In addition, the electronic device ED according to an embodiment may further include a lower module LM disposed below the display module DM.

The electronic device ED according to an embodiment may further include a window adhesive layer AP-W disposed between the display module DM and the window WM, and may also further include a protection film PL and an adhesive protection layer AP-PL disposed above the window WM. In the electronic device ED according to an embodiment, the protection film PL and the adhesive protection layer AP-PL may not be provided. When the protection film PL and the adhesive protection layer AP-PL are omitted, the window WM may be an uppermost surface of the electronic device ED.

The lower module LM may include a support plate MP disposed below the display module DM. The lower module LM may also be referred to as a support member.

The electronic device ED may include a housing HAU accommodating the display module DM, the lower module LM, and the like. The housing HAU may be bonded to the window WM. Although not shown, the housing HAU may further include a hinge structure to facilitate folding or bending. The window WM may be a cover window disposed on the display module DM.

The electronic device ED according to an embodiment may include a window adhesive layer AP-W disposed between display module DM and the window WM. The window adhesive layer AP-W may be an optically clear adhesive film (OCA) or an optically clear adhesive resin layer (OCR). In an embodiment, the window adhesive layer AP-W may not be provided.

The window WM may cover an entire upper surface of the display module DM. The window WM may have a shape corresponding to the shape of the display module DM. The window WM includes glass and may be used as a cover window of the electronic device ED.

The window WM may include a folding portion FP-W and non-folding portions W-NFP1 and W-NFP2. The first non-folding portion W-NFP1 and the second non-folding portion W-NFP2 of the window WM may be spaced apart in the first direction DR1 with the folding portion W-FP therebetween. The folding portion W-FP may be a portion corresponding to the folding region FA1 (FIG. 3A), and the non-folding portions W-NFP1 and W-NFP2 may be portions corresponding to the non-folding regions NFA1 and NFA2 (FIG. 3A).

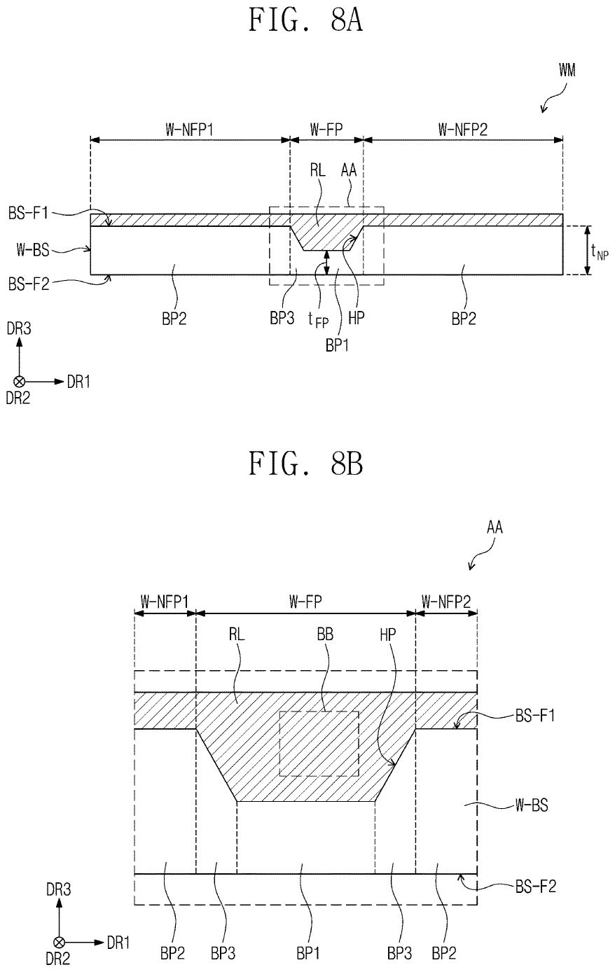

In an embodiment, the window WM includes a base layer W-BS (see FIG. 8A), and a resin layer RL (FIG. 8A) disposed on at least one surface of the base layer W-BS (see FIG. 8A). The base layer comprises one or more surfaces. The resin layer RL (see FIG. 8A) includes a polymer compound derived from a resin composition, which will be described. The base layer W-BS (see FIG. 8A) may be a glass substrate, but is not limited thereto. The base layer W-BS (see FIG. 8A) may be a tempered glass substrate. The base layer W-BS (see FIG. 8A) may be an ultra-thin tempered glass substrate. The window WM according to an embodiment will be described in more detail later.

In reference to FIG. 5, the display module DM may display images according to electrical signals and transmit/receive information on external inputs. The display module DM may include a display region DP-DA and a non-display region DP-NDA. The display region DP-DA may be defined as a region outputting images provided from the display module DM.

The non-display region DP-NDA is adjacent to the display region DP-DA. For example, the non-display region DP-NDA may surround the display region DP-DA. However, this is shown as an example, and the non-display region DP-NDA may be defined in various shapes, and is not limited to any one embodiment. According to an embodiment, the display region DP-DA of the display module DM may correspond to at least a portion of the active region F-AA (FIG. 3A).

In an embodiment, the display module DM may include a display panel DP, FIG. 6. The display panel DP may be a light emitting-type display panel, but is not particularly limited thereto. For example, the display panel DP may be an organic light emitting display panel or an inorganic light emitting display panel. An emission layer of the organic light emitting display panel may include an organic light emitting material. An emission layer of the inorganic light emitting display panel may include quantum dots, quantum rods, and the like.

In reference to FIG. 6, the display module DM may further include an input sensor IS. The input sensor IS may be directly disposed on the display panel DP. The input sensor IS may include a plurality of sensing electrodes. The input sensor IS may detect external inputs using a self-cap method or a mutual-cap method. The input sensor IS may also detect inputs by an active-type input device.

The input sensor IS may be directly formed on the display panel DP through a continuous process when the display panel DP is manufactured. However, the embodiment is not limited thereto, and the input sensor IS may be manufactured as a separate panel from the display panel DP, and be attached to the display panel DP through an adhesive layer (not shown).

In addition, the display module DM may further include an optical layer RCL. The optical layer RCL may serve to reduce reflection by external light. For example, the optical layer RCL may include a polarizing layer or a color filter layer. However, the embodiment of is not limited thereto, and the optical layer RCL may include optical members for improving display quality of the electronic device ED.

In an embodiment, the optical layer RCL may be directly disposed on the input sensor IS. In addition, when the input sensor IS is not provided in the display module DM, the optical layer RCL may be directly disposed on the display panel DP. However, the embodiment is not limited thereto, and the optical layer RCL may be disposed on the display panel DP or the input sensor IS, using a separate adhesive member.

The display module DM may include a folding display portion FP-D and non-folding display portions NFP1-D and NFP2-D. The folding display portion FP-D may be a portion corresponding to the folding region FA1 (FIG. 3A), and the non-folding display portions NFP1-D and NFP2-D may be portions corresponding to the non-folding regions NFA1 and NFA2 (FIG. 3A).

The folding display portion FP-D may correspond to a portion that is folded or bent with respect to the first folding axis FX1 (FIGS. 3B and 3C). The display module DM may include a first non-folding display portion NFP1-D and a second non-folding display portion NFP2-D, and the first non-folding display portion NFP1-D and the second non-folding display portion NFP2-D may be spaced apart with the folding display portion FP-D therebetween.

In the electronic device ED according to an embodiment, the lower module LM may include a support plate MP. In addition, in an embodiment, the lower module LM may further include at least one of a support module SM, a protection layer PF, or a buffer layer CPN. For example, the electronic device ED according to an embodiment may include a support plate MP disposed below a display module DM, a protection layer PF and a buffer layer CPN disposed between the support plate MP and the display module DM, and a support module SM disposed below the support plate MP.

In an embodiment, the support plate MP may be disposed below the display module DM. The support plate MP may include a folding support portion FP-MP and non-folding support portions NFP1-MP and NFP2-MP. The first non-folding support portion NFP1-MP and the second non-folding support portion NFP2-MP of the support plate MP may be spaced apart with the folding support portion FP-MP therebetween. The folding support portion FP-MP may be a portion corresponding to the folding region FA1 (FIG. 3A), and the non-folding support portions NFP1-MP and NFP2-MP may be portions corresponding to the non-folding regions NFA1 and NFA2 (FIG. 3A).

Referring to FIGS. 5 and 6, a protection layer PF may be disposed between the display module DM and the support plate MP. The protection layer PF may be a layer disposed below the display module DM to protect a rear surface of the display module DM. The protection layer PF may overlap the entire display module DM. The protection layer PF may include a polymer material. For example, the protection layer PF may be a polyimide film or a polyethylene terephthalate film. However, this is presented as an example, and the material of the protection layer PF is not limited thereto.

The electronic device ED according to an embodiment may include the support module SM. The support module SM may include a support portion SPM and a filling portion SAP. The support portion SPM may be a portion overlapping most regions of the display module DM. The filling portion SAP may be a portion disposed outside the support portion SPM and overlapping an outer portion of the display module DM.

The support module SM may include support layers SP1 and SP2. The support layers SP1 and SP2 may include a first sub support layer SP1 and a second sub support layer SP2 spaced apart in the first direction DR1. The first sub support layer SP1 and the second sub support layer SP2 may be spaced apart at a portion corresponding to the first folding axis FX1 (FIGS. 3B and 3C). The support layers SP1 and SP2 are spaced apart in the folding region FA1 to serve as the first sub support layer SP1 and the second sub support layer SP2, thereby improving folding or bending characteristics of the electronic device ED. Although not shown, the support layers SP1 and SP2 may include a cushion layer (not shown) and a lower support plate (not shown) which are stacked in a thickness direction.

The support plate (not shown) may include a metal material or a polymer material. For example, the lower support plate may be formed including stainless steel, aluminum, copper, or an alloy thereof.

The cushion layer (not shown) may prevent the support plate MP from being pressed and deformed due to external impact and force. The cushion layer (not shown) may include sponge, foam, or elastomer such as a urethane resin. In addition, the cushion layer (not shown) may be formed including at least one of an acryl-based polymer, a urethane-based polymer, a silicone-based polymer, or an imide-based polymer. However, the embodiment is not limited thereto. The cushion layer (not shown) may be disposed below the support plate MP or below the lower support plate (not shown).

In addition, the support module SM may further include at least one of a shielding layer EMP or an interlayer adhesive layer ILP. The shielding layer EMP may be an electromagnetic wave shielding layer or a heat dissipation layer. In addition, the shielding layer EMP may serve as a bonding layer. The support module SM and the housing HAU may be bonded using the shielding layer EMP. The shielding layer EMP may be disposed below the support layers SP1 and SP2.

The support module SM may further include an interlayer adhesive layer ILP disposed above the support layers SP1 and SP2. The interlayer adhesive layer ILP may bond the support plate MP and the support module SM. The interlayer bonding layer ILP may be provided in the form of a bonding resin layer or an adhesive tape. For example, the interlayer adhesive layer ILP may have a portion overlapping the folding display portion FP-D removed therefrom. However, the embodiment is not limited thereto, and the interlayer adhesive layer ILP may overlap the entire folding display portion FP-D.

The filling portion SAP may be disposed outside the support layers SP1 and SP2. The filling portion SAP may be disposed between the support plate MP and the housing HAU. The filling portion SAP may fill a space between the support plate MP and the housing HAU, and fix the support plate MP.

Referring to FIGS. 5 and 6, the electronic device ED according to an embodiment may include the buffer layer CPN in the lower module LM. The buffer layer CPN may serve as a thickness compensation layer compensating for the thickness below the display module DM or serve as a support layer supporting the display module DM. Unlike what is shown, the buffer layer CPN may not be provided in an embodiment.

Combination of components included in the lower module LM in the electronic device ED according to an embodiment may vary depending on the size and shape of the electronic device ED or operation characteristics of the electronic device ED.

In addition, the electronic device ED according to an embodiment may further include at least one adhesive layer AP1, AP2, or AP3. For example, the first adhesive layer AP1 may be disposed between the display module DM and the protection layer PF, the second adhesive layer AP2 may be disposed between the protection layer PF and the buffer layer CPN, and the third adhesive layer AP3 may be disposed between the support plate MP and the buffer layer CPN. The at least one adhesive layer AP1, AP2, or AP3 may be an optically clear adhesive film (OCA) or an optically clear adhesive resin layer (OCR). However, the embodiment is not limited thereto, and the at least one adhesive layer AP1, AP2, or AP3 may be an adhesive layer having a transmittance of about 80% or less.

The electronic device ED according to an embodiment may further include a protection film PL disposed above the window WM. The protection film PL may be disposed above the window WM to protect the window WM from external environments. However, in the electronic device ED according to an embodiment, the protection film PL may be omitted, and the window WM may be an uppermost surface of the electronic device ED.

The adhesive protection layer AP-PL may be further disposed between the window WM and the protection film PL. The adhesive protection layer AP-PL may be an optically clear adhesive layer. When the electronic device ED according to an embodiment includes the protection film PL, the protection film PL may be a layer exposed to the outside in the electronic device ED.

The protection film PL may have optical properties such as a transmittance of about 90% or greater in a visible light region and a haze value of less than about 1%. The protection film PL may include a polymer film. In addition, the protection film PL may have the polymer film as a base layer and further include functional layers such as a hard coating layer, an anti-fingerprint coating layer, and an antistatic coating layer on the base layer. The protection film PL used in the electronic device ED according to an embodiment may have flexibility.

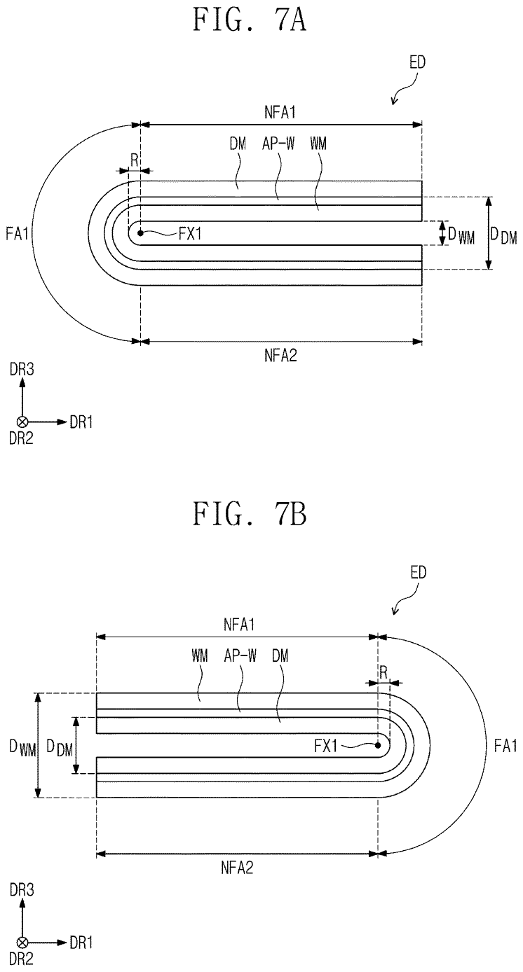

FIGS. 7A and 7B are each views schematically showing a cross-section of an electronic device ED according to an embodiment in a folded state. FIGS. 7A and 7B schematically show only the components of the display module DM, the window adhesive layer AP-W, and the window WM of the electronic device ED.

The drawing shown in FIG. 7A is a cross-section showing an inner-folded state, and in the folded state of the electronic device ED according to an embodiment, a distance D_{WM} between upper surfaces, which face each other, of the window WM may be less than a distance D_{DM} between upper surfaces, which face each other, of the display module DM. In the electronic device ED according to an embodiment, a radius of curvature R of the folding region FA1, which is inner-folded with respect to the first folding axis FX1, may be about 1 mm or less. That is, since the window WM according to an embodiment, which will be described, includes a glass substrate in which a concave portion is defined corresponding to the folding region, the bending radius limit may be reduced such that the radius of curvature R of the folding region FA1 is about 1 mm or less. The concave portion can be of any shape including circular, semi-circular, or geometric such as having an angular well structure, or a combination of circular and angular well surfaces. However, the embodiment is not limited thereto, and the radius of curvature R of the folding region FA1 may be greater than about 1 mm.

The drawing shown in FIG. 7B is a cross-section showing an outer-folded state, and in the folded state of the electronic device ED according to an embodiment, a distance D_{DM} between upper surfaces, which face each other, of the display module DM may be less than a distance D_{WM} between upper surfaces, which face each other, of the window WM. In the electronic device ED according to an embodiment, a radius of curvature R of the folding region FA1, which is outer-folded with respect to the first folding axis FX1, may be about 1 mm or less. That is, since the window WM according to an embodiment, which will be described, includes a glass substrate in which a concave portion is defined corresponding to the folding region, the bending radius limit may be reduced such that the radius of curvature R of the folding region FA1 is about 1 mm or less. However, the embodiment is not limited thereto, and the radius of curvature R of the folding region FA1 may be greater than about 1 mm.

FIG. 8A is a cross-sectional view showing a window according to an embodiment. FIG. 8B is a cross-sectional view showing a portion of a window according to an embodiment. FIG. 8B is a cross-section of a window WM according to an embodiment, corresponding to region AA of FIG. 8A.

Referring to FIGS. 8A and 8B, a window WM according to an embodiment may include a base layer W-BS and a resin layer RL disposed on at least one surface of the base layer W-BS. A concave portion HP may be defined on at least one surface of the base layer W-BS. The resin layer RL may be disposed on one surface of the base layer W-BS in which the concave portion HP is defined.

The base layer W-BS according to an embodiment may include a first non-folding portion W-NFP1, a second non-folding portion W-NFP2, and a folding portion W-FP disposed between the first non-folding portion W-NFP1 and the second non-folding portion W-NFP2. The first non-folding portion W-NFP1 and the second non-folding portion W-NFP2 of the base layer W-BS may be spaced apart in the first direction DR1 with the folding portion W-FP therebetween. The folding portion W-FP may be a portion corresponding to the folding region FA1 (see FIG. 3A), and the non-folding portions W-NFP1 and W-NFP2 may be portions corresponding to the non-folding regions NFA1 and NFA2 (see FIG. 3A). The phrase “a region/portion corresponds to a region/portion” indicates that the regions/portions overlap each other, but they are not limited to having the same size of area.

In the window WM according to an embodiment, the base layer W-BS may be a tempered glass substrate. The base layer W-BS may be an ultra-thin tempered glass substrate.

In the window WM according to an embodiment, the base layer W-BS may include a first base surface BS-F1 and a second base surface BS-F2 that oppose each other with respect to the third direction DR3. In the window WM according to an embodiment, the concave portion HP may be defined in at least one of the first base surface BS-F1 or the second base surface BS-F2. For example, the concave portion HP may be defined in the first base surface BS-F1 of the base layer W-BS. However, the embodiment of the disclosure is not limited thereto, and unlike what is shown in FIG. 8A, the concave portion HP may be defined in each of the first base surface BS-F1 and the second base surface BS-F2 of the base layer W-BS.

In the window WM according to an embodiment, the concave portion HP may be defined in the first base surface BS-F1 of the base layer W-BS. The concave portion HP may be a portion formed corresponding to the folding portion W-FP. That is, the concave portion HP may be defined on the first base surface BS-F1 so as to overlap the folding portion W-FP. The concave portion HP may be defined on the first base surface BS-F1 of the base layer W-BS, and may be defined to be concavely recessed in a direction from the first base surface BS-F1 to the second base surface BS-F2 of the base layer W-BS.

The resin layer RL may be disposed on one surface of the base layer W-BS in which the concave portion HP is defined. The resin layer RL may be disposed on the first base surface BS-F1 of the base layer W-BS in which the concave portion HP is defined. However, the embodiment is not limited thereto, and unlike what is shown in FIG. 8A, the concave portion HP may be defined on each of the first and second base surfaces BS-F1 and BS-F2 of the base layer W-BS, and in this case, the resin layer RL may be disposed on each of the first and second base surfaces BS-F1 and BS-F2. The resin layer RL may be disposed on one surface of the base layer W-BS to fill the concave portion HP defined in the folding portion W-FP of the window WM. The resin layer RL may entirely fill the concave portion HP. The resin layer RL may fill the concave portion HP and may be disposed to overlap the first non-folding portion W-NFP1, the folding portion W-FP, and the second non-folding portion W-NFP2 of the base layer W-BS.

The concave portion HP defined in the folding portion W-FP of the window WM may be filled with the resin layer RL, thereby mitigating quality degradation caused by the concave portion HP and enhancing mechanical strength in the folding portion W-FP.

The concave portion HP may be defined on the first base surface BS-F1 of the base layer W-BS through a slimming process. In the slimming process, physical polishing methods or chemical polishing methods may be used. In addition, in an embodiment, the concave portion HP may be defined by slimming one surface of the base layer W-BS, using a laser.

In an embodiment, a portion of the base layer W-BS in which the concave portion HP is defined may be thinner than other portions. That is, in an embodiment, in the base layer W-BS, a first average thickness t_{FP} of a portion corresponding to the folding portion W-FP may be less than a second average thickness t_{NP} of a portion corresponding to the non-folding portions W-NFP1 and W-NFP2. The window WM according to an embodiment may include the base layer W-BS which is relatively thinner in the portion corresponding to the folding portion W-FP than in the portion corresponding to the non-folding portions W-NFP1 and W-NFP2, and thus, may have good folding properties.

Referring to FIG. 8B, the base layer W-BS may include a first base portion BP1 corresponding to the folding portion W-FP, a second base portion BP2 corresponding to the non-folding portions W-NFP1 and W-NFP2, and a third base portion BP3 disposed between the first base portion BP1 and the second base portion BP2. The third base portion BP3 may be a portion whose thickness increases in a direction from the first base portion BP1 to the second base portion BP2. In an embodiment, an average thickness of the first base portion BP1 may be less than an average thickness of the second base portion BP2.

In an embodiment, the first base portion BP1 and the third base portion BP3 may be portions corresponding to the folding portion W-FP. In the base layer W-BS, the first base portion BP1 may correspond to a flat portion where the first base surface BS-F1 is parallel to the second base surface BS-F2. The third base portion BP3 may correspond to a portion where the first base surface BS-F1 is an inclined surface. The concave portion HP formed on the first base surface BS-F1 adjacent to the resin layer RL in the base layer W-BS may be defined by the first base portion BP1 and the third base portion BP3. As described above, the resin layer RL may fill the concave portion HP. The resin layer RL may be in contact with each of the first base portion BP1 and the third base portion BP3.

In a cross-section parallel to a plane defined by the first direction DR1 and the third direction DR3, the first base surface BS-F1 corresponding to the third base portion BP3 may have a linear shape connecting the first base portion BP1 and the first base surface BS-F1 corresponding to the second base portion BP2. In an embodiment, the concave portion HP may be defined by the first base surface BS-F1 corresponding to the first base portion BP1 and the first base surface BS-F1 corresponding to the third base portion BP3. However, the embodiment is not limited thereto, and unlike what is shown in FIG. 8B, one surface of the third base portion BP3 defining the concave portion HP may have a curved surface shape.

In an embodiment, the shape of the concave portion HP defined in the base layer W-BS is not limited to what is shown in FIGS. 8A and 8B. The shape of the concave portion HP may be variously modified by appropriately adjusting the thickness of the first base portion BP and the second base portion BP2, or the inclination angle of the third base portion BP3.

The resin layer RL may be a filling layer that fills the concave portion HP. The resin layer RL may be disposed to overlap the folding portion W-FP and the non-folding portions W-NFP1 and W-NFP2. However, the embodiment is not limited thereto, and unlike what is shown in FIGS. 8A and 8B, the resin layer RL may overlap the folding portion W-FP and may not overlap the non-folding portions W-NFP1 and W-NFP2. That is, the resin layer RL may be disposed on one surface of the base layer W-BS where the concave portion HP is defined, and may not be disposed on one surface of the base layer W-BS where the concave portion HP is not defined.

The resin layer RL may be formed from a resin composition including a siloxane oligomer and a first organic compound represented by Formula 1, which will be described later. The resin layer RL may be formed by providing a resin composition including a siloxane oligomer and a first organic compound on a base layer W-BS through a coating method or the like and curing the resin composition. The resin layer RL may be formed by thermally curing or photocuring a resin composition including a siloxane oligomer and a first organic compound. For example, the resin layer RL may be formed by photocuring a resin composition. The resin layer RL may include a polymer compound derived from a resin composition including a siloxane oligomer and a first organic compound.

In an embodiment, the first organic compound may be represented by Formula 1.

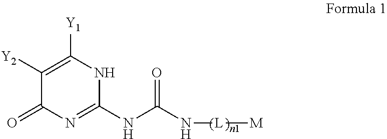

In Formula 1, Y₁ and Y₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Y₁ and Y₂ may each independently be a hydrogen atom or a substituted or unsubstituted methyl group.

In Formula 1, M indicates a polymerizable functional group. In an embodiment, M may be a substituted or unsubstituted (meth)acrylate group, a substituted or unsubstituted vinyl group, a substituted or unsubstituted epoxy group, or a substituted or unsubstituted oxetanyl group. For example, M may be a substituted or unsubstituted (meth)acrylate group.

In Formula 1, each L is independently a direct linkage, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, L may be a substituted or unsubstituted alkyl group having 1 to 20 carbon atoms.

In Formula 1, n1 is an integer of 1 to 20. For example, n1 is an integer of 1 to 10. If n is 2 to 10, then each L can be the same or different from another L.

In an embodiment, the first organic compound represented by Formula 1 may be represented by Formula 1-1.

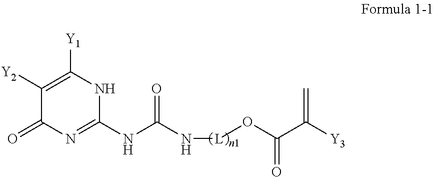

Formula 1-1 shows a case in which the type of M in Formula 1 is specified. Formula 1-1 corresponds to a case where M in Formula 1 is a substituted or unsubstituted (meth)acrylate group.

In Formula 1-1, Y₃ may be a hydrogen atom or a substituted or unsubstituted alkyl group having 1 to 20 carbon atoms. For example, Y₃ may be a hydrogen atom or an unsubstituted methyl group.

In an embodiment, the siloxane oligomer may include a silsesquioxane compound including at least one polymerizable functional group. The siloxane oligomer may include a silsesquioxane compound including at least one polymerizable functional group selected from a (meth)acrylate group, a vinyl group, an epoxy group, or an oxetanyl group. The siloxane oligomer may include a silsesquioxane compound including at least one (meth)acrylate group.

In an embodiment, the siloxane oligomer may be a silsesquioxane compound including at least one polymerizable functional group. The siloxane oligomer may be a silsesquioxane compound including at least one (meth)acrylate group.

In an embodiment, the silsesquioxane compound may be cage-type, ladder-type, or random-type. In an embodiment, the siloxane oligomer may include at least one of a cage-type silsesquioxane compound, a ladder-type silsesquioxane compound, or a random-type silsesquioxane compound. The silsesquioxane compound may have a cage structure, a ladder structure, and a random structure depending on the structure and form of a crosslinking bond. In this case, the cage structure may include an incomplete cage structure in which a portion of a cage is opened, in addition to a complete cage structure. A silsesquioxane compound having a cage structure may be referred to as polyhedral oligomeric silsesquioxanes (POSS).

In an embodiment, the siloxane oligomer may include a unit of Formula S:

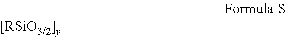

In Formula S, R is a hydrogen atom, a hydroxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 2, at least one of R groups may have a polymerizable functional group bonded to a terminal. In Formula 2, at least one of R groups may be a substituted or unsubstituted alkyl group having 1 to 20 carbon atoms and having a (meth)acrylate group, a vinyl group, an epoxy group, or an oxetanyl group bonded to a terminal.

In Formulas S, y is an integer of 6 to 100. When the siloxane oligomer represented by Formula S is a silsesquioxane compound having a cage structure, y may be 6, 8, 10, or 12.

In an embodiment, the siloxane oligomer may be a silsesquioxane compound including a silicon atom and an alkyl group having 1 to 20 carbon atoms, which is bonded to the silicon atom and including a polymerizable functional group at a terminal. For example, the siloxane oligomer may be a silsesquioxane compound including a silicon atom and an alkyl group having 1 to 20 carbon atoms, which is bonded to the silicon atom and including a (meth)acrylate group at a terminal.

In an embodiment, the siloxane oligomer may be a ladder-type silsesquioxane compound represented by Formula A, a random-type silsesquioxane compound represented by Formula B, or a cage-type silsesquioxane compound represented by Formula C. However, the embodiment is not limited thereto, and the siloxane oligomer may have various shapes depending on the structure and form of the cross-linking bond of the silsesquioxane compound.

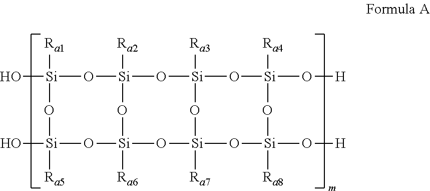

In Formula A, Rₐ₁ to Rₐ₈ are each independently a hydrogen atom, a hydroxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula A, at least one of Rₐ₁ to Rₐ₈ may have a polymerizable functional group bonded to a terminal. In Formula A, at least one of Rₐ₁ to Rₐ₈ may be a substituted or unsubstituted alkyl group having 1 to 20 carbon atoms and having a (meth)acrylate group, a vinyl group, an epoxy group, or an oxetanyl group bonded to a terminal. For example, in Formula A, each of Rₐ₁ to Rₐ₈ may be a substituted or unsubstituted alkyl group having 1 to 20 carbon atoms and having a (meth)acrylate group bonded to a terminal.

In Formula A, m is an integer of 2 to 25.

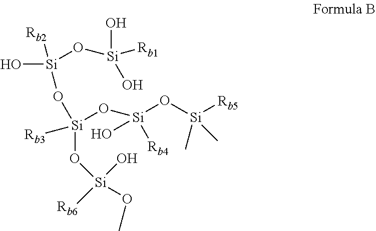

In Formula B, R_{b1} to R_{b6} are each independently a hydrogen atom, a hydroxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula B, at least one of R_{b1} to R_{b6} may have a polymerizable functional group bonded to a terminal. In Formula B, at least one of R_{b1} to R_{b6} may be a substituted or unsubstituted alkyl group having 1 to 20 carbon atoms and having a (meth)acrylate group, a vinyl group, an epoxy group, or an oxetanyl group bonded to a terminal. For example, in Formula B, each of R_{b1} to R_{b6} may be a substituted or unsubstituted alkyl group having 1 to 20 carbon atoms and having a (meth)acrylate group bonded to a terminal.

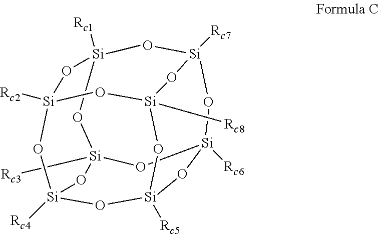

In Formula C, R_{c1} to R_{c8} are each independently a hydrogen atom, a hydroxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula C, at least one of R_{c1} to R_{c8} may have a polymerizable functional group bonded to a terminal. In Formula C, at least one of R_{c1} to R_{c8} may be a substituted or unsubstituted alkyl group having 1 to 20 carbon atoms and having a (meth)acrylate group, a vinyl group, an epoxy group, or an oxetanyl group bonded to a terminal. For example, in Formula C, each of R_{c1} to R_{c8} may be a substituted or unsubstituted alkyl group having 1 to 20 carbon atoms and having a (meth)acrylate group bonded to a terminal.

In an embodiment, Formula A may be represented by Formula A1, Formula B may be represented by Formula B1, and Formula C may be represented by Formula C1. Formula A1, Formula B2, and Formula C1 each indicate cases in which specific types of substituents are linked to the silicon atom in Formula A, Formula B, and Formula C. In an embodiment, Formula A1 indicates a case where Rₐ₁ to Rₐ₈ in Formula A are each an alkyl group with a (meth)acrylate group bonded to a terminal, Formula B1 indicates a case where R_{b1} to R_{b6} in Formula B are each an alkyl group with a (meth)acrylate group bonded to a terminal, and Formula C1 indicates a case where R_{c1} to R_{c8} in Formula C are each an alkyl group with a (meth)acrylate group bonded to a terminal.

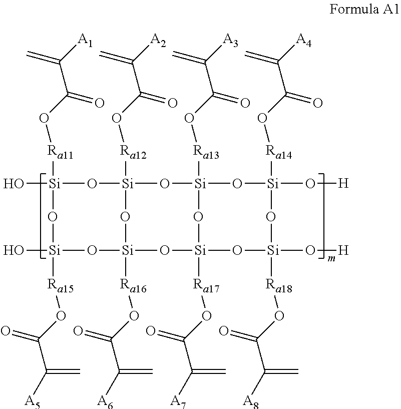

In Formula A1, Rₐ₁₁ to Rₐ₁₈ may each independently be a substituted or unsubstituted divalent alkyl group having 1 to 20 carbon atoms.

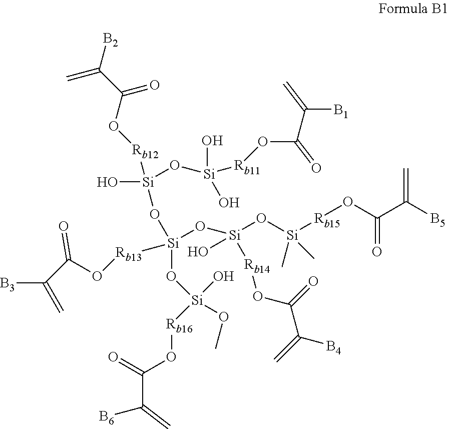

In Formula B1, R_{b11} to R_{b16} may each independently be a substituted or unsubstituted divalent alkyl group having 1 to 20 carbon atoms.

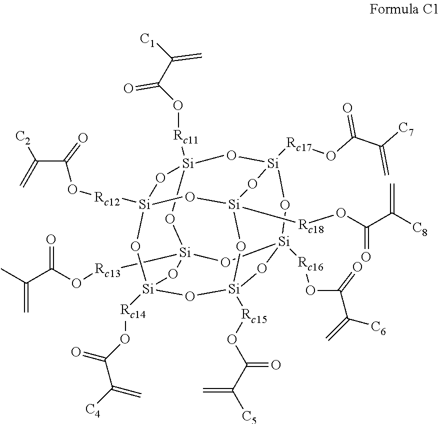

In Formula C1, R_{c11} to R_{c18} may each independently be a substituted or unsubstituted divalent alkyl group having 1 to 20 carbon atoms.

In an embodiment, the resin composition for forming the resin layer RL may further include a second organic compound in addition to the siloxane oligomer and the first organic compound represented by Formula 1. The second organic compound may be different from the first organic compound. The resin layer RL may be formed by providing a resin composition including a siloxane oligomer, a first organic compound, and a second organic compound on a base layer W-BS through a coating method or the like and curing the resin composition. The resin layer RL may be formed by thermally curing or photocuring a resin composition including a siloxane oligomer, a first organic compound, and a second organic compound. The resin layer RL may include a polymer compound derived from a resin composition including a siloxane oligomer, a first organic compound, and a second organic compound.

In an embodiment, the second organic compound may include a polymerizable monomer. The second organic compound may be a polymerizable monomer including a (meth)acrylate group, a vinyl group, an epoxy group, or an oxetanyl group.

In an embodiment, the second organic compound may be a (meth)acrylate monomer. For example, the second organic compound may include at least one of an alkyl (meth)acrylate, a hydroxyalkyl (meth)acrylate, a polyethylene glycol alkyl ether methacrylate, a perfluorinated alkyl (meth)acrylate, and a silicone (meth)acrylate.

In an embodiment, the second organic compound may be an alkyl (meth)acrylate monomer. For example, the second organic compound may be a monomer represented by Formula 2.

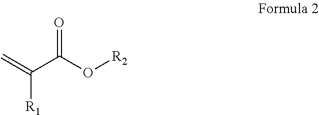

In Formula 2, R₁ may be a hydrogen atom or a substituted or unsubstituted alkyl group having 1 to 20 carbon atoms. For example, R₁ may be a hydrogen atom or an unsubstituted methyl group.

In Formula 2, R₂ is a substituted or unsubstituted alkyl group having 1 to 20 carbon atoms.

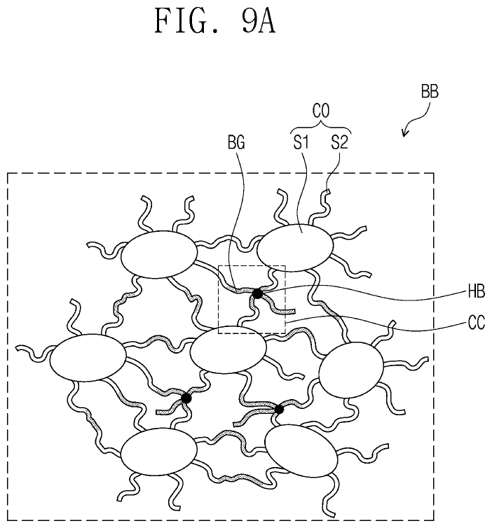

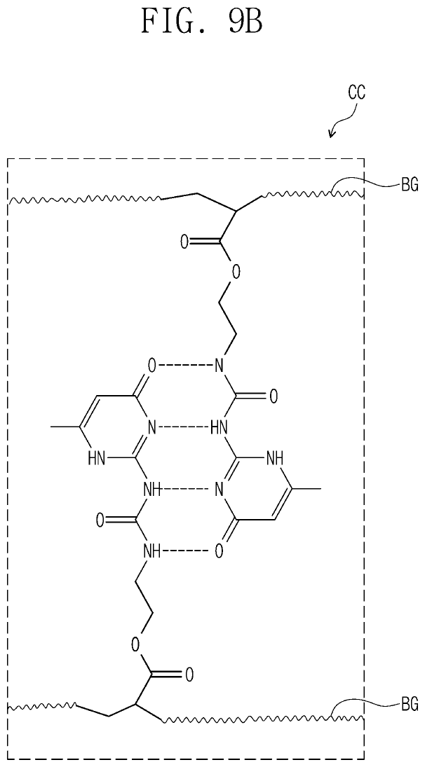

FIG. 9A schematically shows a polymer compound included in a resin layer according to an embodiment, as a portion corresponding to region BB of FIG. 8B. FIG. 9B is a view enlarging a portion of a polymer compound included in a resin layer, as a portion corresponding to region CC of FIG. 9B.

The resin layer RL may include a polymer compound derived from a resin composition including a siloxane oligomer and a first organic compound. The polymer compound may be formed through a polymerization reaction of a siloxane oligomer and a first organic compound. The polymer compound of the resin layer RL may be formed by including a condensate of the siloxane oligomer and the first organic compound. In addition, the resin layer RL may include a polymer compound derived from a resin composition including a siloxane oligomer, a first organic compound, and a second organic compound. The polymer compound may be formed through a polymerization reaction of the siloxane oligomer, the first organic compound, and the second organic compound. The polymer compound of the resin layer RL may be a shape memory type self-healing polymer compound.

Referring to FIG. 9A, the polymer compound may include a plurality of cores CO including a siloxane oligomer, and a plurality of linkages (or bridge linkages) BG disposed between the plurality of cores CO and connecting the plurality of cores CO.

The cores CO may include a siloxane oligomer. The cores CO may include a first portion S1 including a siloxane unit, and a second portion S2 connected to the first portion S1, in which the second portion S2 includes a polymerizable functional group. The first portion S1 may be a portion including a siloxane unit represented by SiO_{3/2}. The second portion S2 may be a substituent connected to a silicon atom of the first portion and including a polymerizable functional group at a terminal.

The polymer compound included in the resin layer RL may have a three-dimensional network structure. In the polymer compound included in the resin layer RL, the plurality of cores CO may serve to impart shape memory properties to the resin layer RL. The plurality of cores CO may serve to prevent polymer chains from being subjected to slip, creep, or the like caused by deformation. The plurality of cores CO may be bonded to each other through physical entanglement, covalent bonding, or chemical or physical cross-linking.

The linkages BG may be disposed between the plurality of cores CO to connect the plurality of cores CO. The linkages BG may form a bond with the plurality of cores CO through the second portion S2 of the plurality of cores CO. The linkages BG may be cured with a curable functional group included in the second portion S2 through a polymerization reaction to form a bond with the plurality of cores CO.

The linkages BG may include a first organic compound. Alternatively, when the resin composition further includes a second organic compound, the linkages BG may include the first organic compound and the second organic compound. The first organic compound may serve to connect adjacent linkages BG through a hydrogen bonding functional group. The second organic compound, along with the first organic compound, may be a component forming the linkages BG, and may serve to control the length of the linkages BG, thereby controlling hydrogen bond density, crosslinking density, and the like.

An adjacent Linkage BG among the plurality of linkages BG that is positionally adjacent to another linkage BG may be connected to each other through hydrogen bonding. That is, the polymer compound may include a bonding portion HB in which adjacent linkages BG are connected through hydrogen bonding. FIG. 9B is a view enlarging a bonding portion HB of a polymer compound. Referring to FIG. 9B, the bonding portion HB may be formed between adjacent linkages BG. The linkages BG may form hydrogen bonds through hydrogen bonding functional groups included in a first organic compound. The first organic compound may include a hydrogen bond donor and a hydrogen bond acceptor in one molecule and may form hydrogen bonds with other adjacent first organic compounds. As shown in FIG. 9B, the first organic compound may form four hydrogen bonds with other adjacent first organic compounds.

In the polymer compound, neighboring linkages BG among the plurality of linkages BG may form bonding portions HB that are bonded to each other through hydrogen bonds. The bonding portions HB may include hydrogen bonds formed by the bonding of neighboring linkages BG. The bonding portions HB may include hydrogen bonds formed through the first organic compound included in the neighboring linkages BG. The neighboring linkages BG may be connected to each other through hydrogen bonds via hydrogen bonding functional groups included in the first organic compound.

The polymer compound includes the bonding portion HB in which adjacent linkages BG are connected to each other through hydrogen bonds, and may thus exhibit excellent self-healing characteristics. The polymer compound may form a relatively strong bond between adjacent linkages BG due to the structural characteristics of the first organic compound, and accordingly, even when deformation or damage occurs due to external stimuli, these bonding characteristics may allow the polymer compound to be restored or healed to an original form.

In an embodiment, the linkages BG may include a repeating unit represented by Formula G. In the repeating unit represented by Formula G, it is shown that a first organic compound represented by Formula 1-1 is included and a second organic compound represented by Formula 2 is included as an example, but the embodiment is not limited thereto.

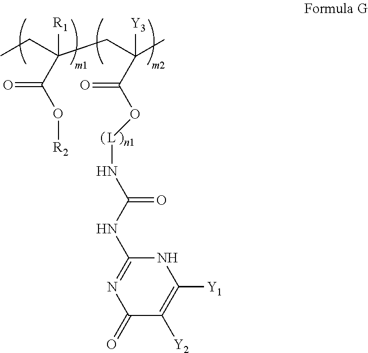

In Formula G, m1 and m2 are each natural numbers. For example, m1 and m2 may each be natural numbers from 1 to 100, but are not limited thereto.

In Formula G, the same descriptions as in Formulas 1 and 1-1 may also apply to Y₁ to Y₃, L, and n1.

In Formula G, the same descriptions as in Formula 2 may also apply to R₁ and R₂.

A resin layer RL included in a window WM may be optically transparent. Accordingly, the window WM including the resin layer RL may exhibit excellent optical properties. The resin layer RL according to an embodiment may have a high transmittance of about 90% or greater in a visible light range of about 400 nm to about 700 nm.

The resin layer RL may have a tensile strength of about 0.1 MPa at about 25° C. For example, the resin layer RL may have a tensile strength of about 0.1 MPa to about 10 MPa at about 25° C. The window WM includes the resin layer RL having a high tensile strength of about 0.1 MPa or greater and thus may have excellent mechanical strength.

The polymer compound included in the resin layer RL, as a polymer subjected to a reaction by including a siloxane oligomer and a first organic compound, includes a siloxane oligomer portion and a first organic compound represented by Formula 1 together, and may thus exhibit excellent self-restoring characteristics, excellent mechanical properties, and satisfactory optical properties of high transmittance and low yellow index. The resin layer RL according to an embodiment may have a yellow index of about 2 or less. The resin layer according to an embodiment may have a high light transmittance of about 90% or greater and a low yellow index of about 2 or less. Accordingly, the window according to an embodiment may have high transparency, and thus be applied to electronic devices, contributing to excellent optical properties.

The window WM according to an embodiment may exhibit both shape memory characteristics and self-healing characteristics since the resin layer RL includes a polymer compound derived from a resin composition including a siloxane oligomer and a first organic compound. Accordingly, when deformation or damage occurs in the resin layer RL due to external stimuli, the deformed shape may be effectively restored, and the damage may be healed or reduced. When a flexible window WM repeatedly undergoes folding or remains in a folded state, a region corresponding to a folding region may be deformed. Accordingly, when an electronic device is in an unfolded state, a crease may occur in a region corresponding to the folding region. Due to such deformation, an image is distorted in the folding region, resulting in a degradation of image quality. Herein, by introducing a polymer compound derived from a resin composition including a siloxane oligomer and a first organic compound into a resin layer, even when a crease is formed in a folding region, the crease may be restored to an original state through shape memory characteristics. Accordingly, image distortion in the folding region may be prevented, and an electronic device may have improved display quality. In addition, the resin layer RL includes a polymer compound derived from a resin composition including a siloxane oligomer and a first organic compound, and accordingly, even when scratches or other damage occur on a window surface, the self-healing characteristics may allow the damaged portion to heal itself, thereby improving the durability of the window. Accordingly, the electronic device may have further improved appearance characteristics.

In addition, the resin layer RL includes a polymer compound derived from a resin composition including a siloxane oligomer and a first organic compound, and may thus exhibit excellent self-restoring characteristics as well as excellent mechanical properties. A typical self-healing polymer film manufactured from a ureidopyrimidinone (UPy) derivative compound exhibits excellent self-restoring characteristics, but has insufficient mechanical properties in tensile strength and hardness, and thus is limited in being applied as a window of an electronic device. The window disposed on an upper portion of the electronic device requires high mechanical properties to protect the electronic device from external stimuli, but the typical self-healing polymer film does not satisfy such mechanical properties. Herein, by introducing a polymer compound formed by a condensate of a first organic compound including a ureidopyrimidinone derivative and a siloxane oligomer into a resin layer, both high mechanical properties required for a window of an electronic device and excellent self-restoring characteristics may be achieved.

In an embodiment, the window WM includes a base layer W-BS, and a resin layer RL disposed on the base layer W-BS and including a polymer compound derived from a resin composition including a siloxane oligomer and a first organic compound, and may thus exhibit excellent self-restoring characteristics, excellent optical properties, and excellent durability together.

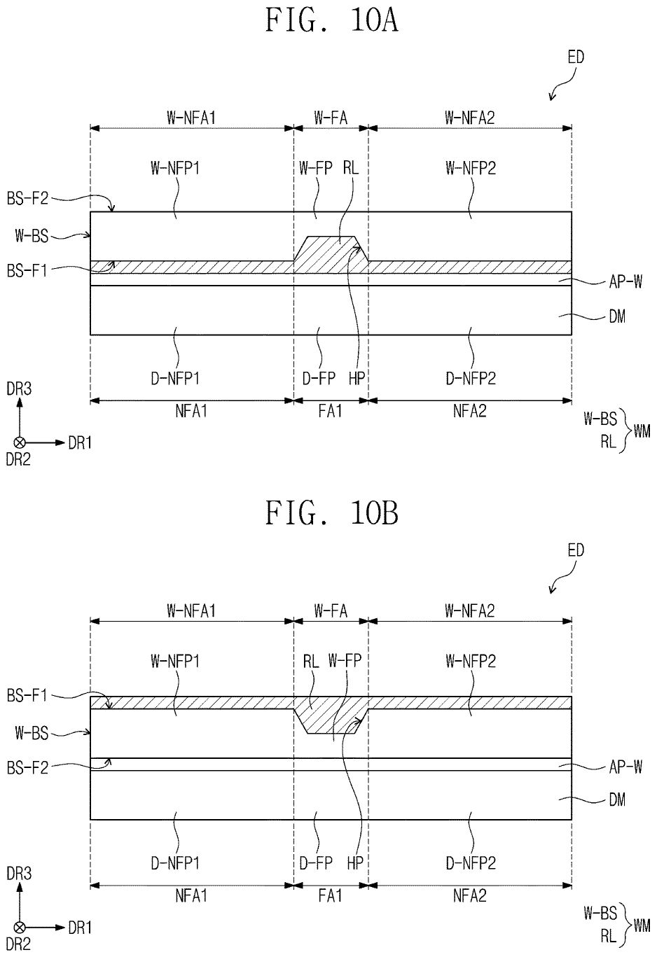

FIGS. 10A and 10B are each views schematically showing a cross-section of one component included in an electronic device ED according to an embodiment. FIGS. 10A and 10B schematically show only the components of a display module DM, a window adhesive layer AP-W, and a window WM of an electronic device ED.

Referring to FIG. 10A, in the window WM according to an embodiment, a first base surface BS-F1 of a base layer W-BS may be positioned closer to the display module DM than a second base surface BS-F2 is. In the window WM according to an embodiment, the base layer W-BS may be disposed such that the first base surface BS-F1 in which a concave portion HP is defined is positioned closer to the display module DM than the second base surface BS-F2 is. The first base surface BS-F1 may be disposed to be adjacent to the display module DM, and the second base surface BS-F2 may be disposed to face the first base surface BS-F1 in the third direction DR3 and be spaced apart from the display module DM. In the electronic device ED according to an embodiment, the second base surface BS-F2 may be exposed to the outside. In addition, in the electronic device ED according to an embodiment, the resin layer RL may be disposed to be adjacent to the display module DM.

When the electronic device ED according to an embodiment shown in FIG. 10A is in-folded as in the operation of FIG. 3B, the second base surface BS-F2 of the base layer W-BS corresponding to a first non-folded portion W-NFP1 and the second base surface BS-F2 of the base layer W-BS corresponding to a second non-folded portion W-NFP2 may be folded to be adjacent, facing each other. In addition, when the electronic device ED according to an embodiment shown in FIG. 10A is out-folded as in the operation of FIG. 3C, the second base surface BS-F2 of the base layer W-BS corresponding to the first non-folded portion W-NFP1 and the second base surface BS-F2 of the base layer W-BS corresponding to the second non-folded portion W-NFP2 may be exposed to the outside.

The electronic device ED shown in FIG. 10B is the one different from the electronic device ED shown in FIG. 10A in the arrangement direction of the window WM. The electronic device ED shown in FIG. 10B is the one in which the second base surface BS-F2 of the base layer W-BS is disposed closer to the display module DM than the first base surface BS-F1 is, compared to the electronic device ED shown in FIG. 10A.

Referring to FIG. 10B, in the window WM of an embodiment, the second base surface BS-F2 of the base layer W-BS may be positioned closer to the display module DM than the first base surface BS-F1 is. In the window WM according to an embodiment, the base layer W-BS may be disposed such that the second base surface BS-F2 in which the concave portion HP is not defined is positioned closer to the display module DM than the first base surface BS-F1 in which the concave portion HP is defined. The second base surface BS-F2 may be disposed to be adjacent to the display module DM, and the first base surface BS-F1 may be disposed to face the second base surface BS-F2 in the third direction DR3 and be spaced apart from the display module DM. In the electronic device ED according to an embodiment, the resin layer RL may be spaced apart from the display module DM.

In the electronic device ED according to an embodiment shown in FIG. 10B, the resin layer RL may be exposed to the outside. However, the embodiment is not limited thereto, and the window WM according to an embodiment may further include an additional protection layer disposed on the first base surface BS-F1 of the base layer W-BS. In this case, the additional protective layer may be disposed on the resin layer RL. The resin layer RL may be disposed between the base layer W-BS and the additional protection layer. The additional protection layer may overlap all of the first non-folding portion W-NFP1, the folding portion W-FP, and the second non-folding portion W-NFP2 of the base layer W-BS.

When the electronic device ED according to an embodiment shown in FIG. 10B is in-folded as in the operation of FIG. 3B, the first base surface BS-F1 of the base layer W-BS corresponding to the first non-folded portion W-NFP1 and the first base surface BS-F1 of the base layer W-BS corresponding to the second non-folded portion W-NFP2 may be folded to be adjacent, facing each other. In addition, when the electronic device ED according to an embodiment shown in FIG. 10B is out-folded as in the operation of FIG. 3C, the first base surface BS-F1 of the base layer W-BS corresponding to the first non-folded portion W-NFP1 and the first base surface BS-F1 of the base layer W-BS corresponding to the second non-folded portion W-NFP2 may be exposed to the outside.

Referring to FIGS. 10A and 10B, in the electronic device ED according to an embodiment, the window WM may include a first window non-folding region W-NFA1, a second window non-folding region W-NFA2, and a window folding region W-FA disposed between the first window non-folding region W-NFA1 and the second window non-folding region W-NFA2. The first window non-folding region W-NFA1 and the second window non-folding region W-NFA2 may be spaced apart in the first direction DR1 with the window folding region W-FA therebetween. The window folding region W-FA may be a portion corresponding to the folding region FA1 of the electronic device ED, the first window non-folding region W-NFA1 may be a portion corresponding to the first non-folding region NFA1 of the electronic device ED, and the second window non-folding region W-NFA2 may be a portion corresponding to the second non-folding region NFA2 of the electronic device ED.

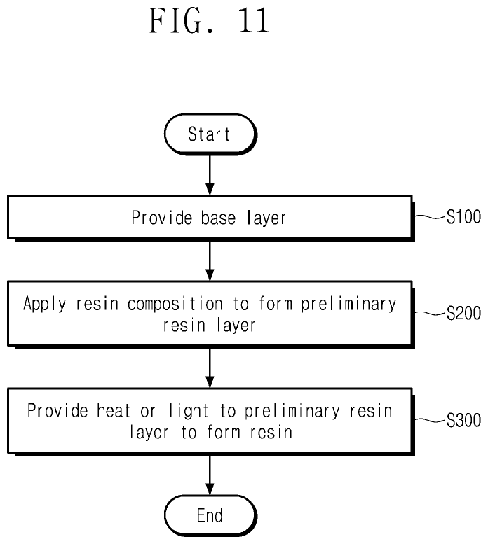

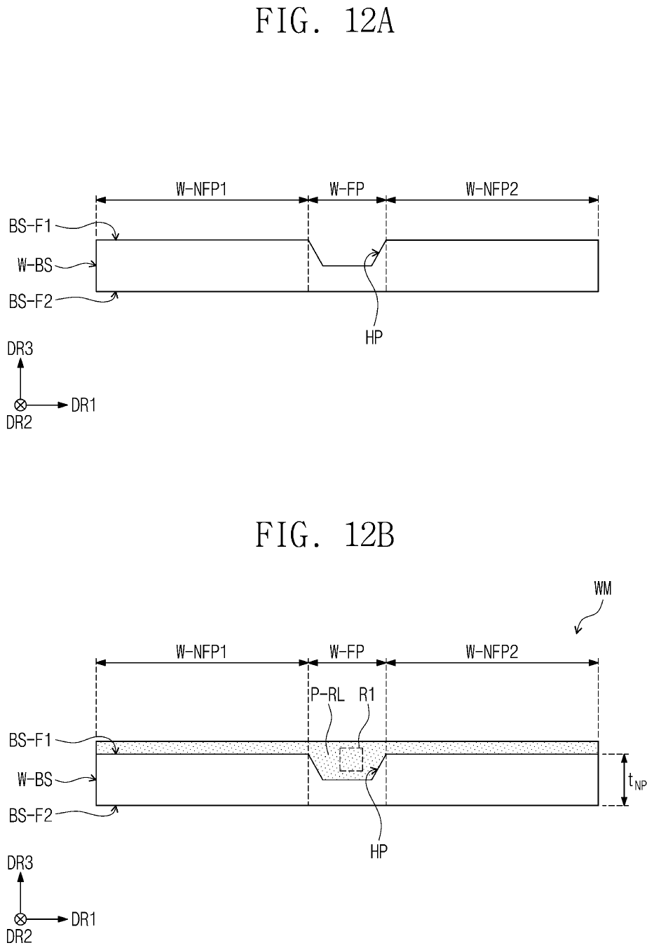

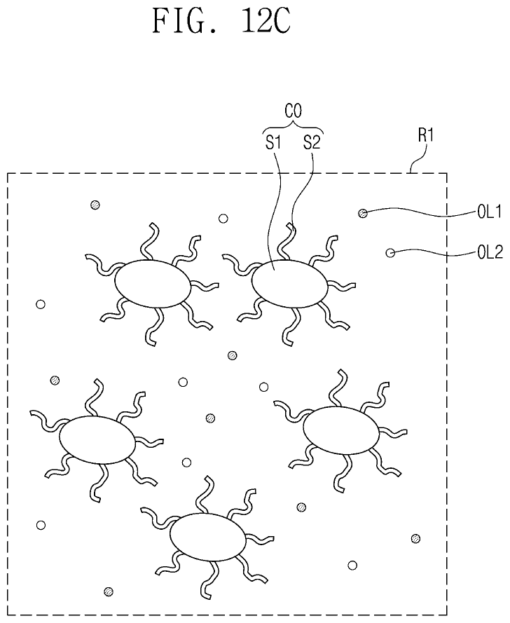

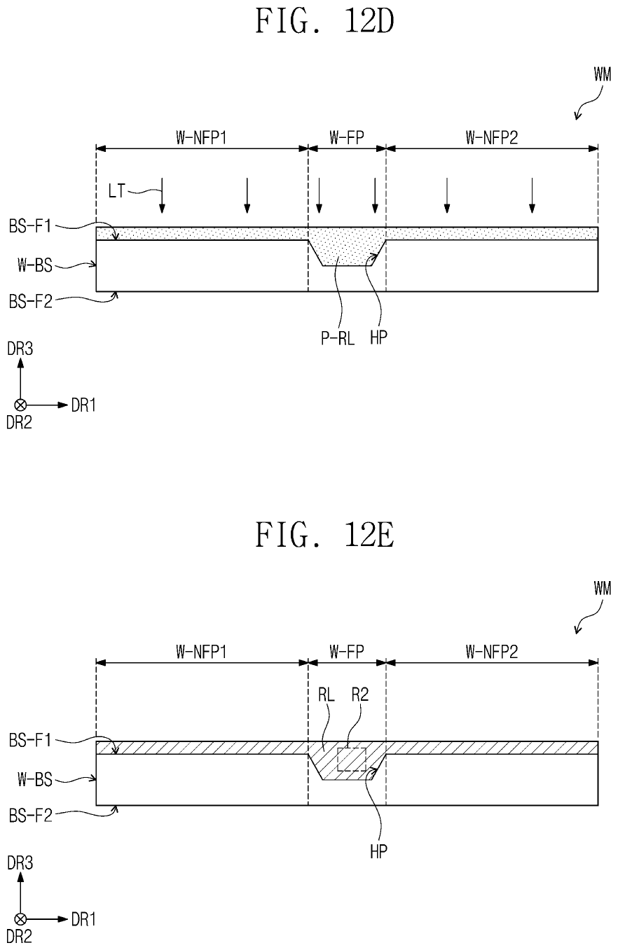

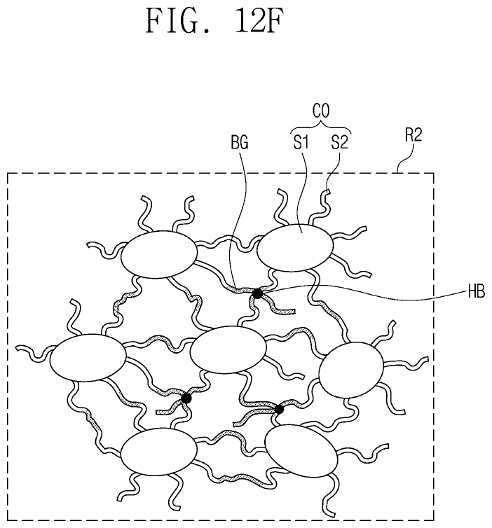

Hereinafter, a method for manufacturing a window according to an embodiment is described with reference to FIGS. 11 and 12A to 12F. In describing the method for manufacturing a window according to an embodiment, the descriptions of the window according to an embodiment previously presented may be applied. A window manufactured through the method for manufacturing a window according to an embodiment may be applied to the electronic device previously described. Hereinafter, in the description of the method for manufacturing a window according to an embodiment, duplicated descriptions as those described for the window according to an embodiment will not be provided again, and different features will be mainly described.

The method for manufacturing a window according to an embodiment may indicate the method for manufacturing a window WM according to an embodiment described in FIGS. 3A to 10B. An embodiment provides a method for manufacturing a window WM disposed on a display module DM of an electronic device ED.

FIG. 11 is a flowchart showing a method for manufacturing a window according to an embodiment of the disclosure.

Referring to FIG. 11, the method for manufacturing a window according to an embodiment includes providing a base layer (S100), applying a resin composition to form a preliminary resin layer (S200), and providing heat or light to the preliminary resin layer to form a resin layer (S300).

FIGS. 12A to 12F are views showing some processes in a method for manufacturing a window according to an embodiment of the disclosure. FIG. 12A shows providing a base layer. FIG. 12B shows applying a resin composition to form a preliminary resin layer. FIG. 12C is a view showing a portion corresponding to region “R1” of FIG. 12B. FIGS. 12D and 12E show providing heat or light to the preliminary resin layer to form a resin layer. FIG. 12F is a view showing a portion corresponding to region “R2” of FIG. 12D.

FIG. 12A is a view showing preparing a base layer W-BS (S100). The base layer W-BS may serve as a substrate for applying a liquid resin composition. The base layer W-BS may be a tempered glass substrate. The base layer W-BS may be an ultra-thin tempered glass substrate.

The base layer W-BS may include a first non-folding portion W-NFP1, a second non-folding portion W-NFP2, and a folding portion W-FP disposed between the first non-folding portion W-NFP1 and the second non-folding portion W-NFP2. A concave portion HP may be formed on at least one surface of the base layer W-BS to overlap the folding portion W-FP. As shown in FIG. 12A, a concave portion HP corresponding to the folding portion W-FP may be defined on a first base surface BS-F1 of the base layer W-BS. The concave portion HP may be defined to be concavely recessed in a direction from the first base surface BS-F1 to a second base surface BS-F2 of the base layer W-BS.

FIG. 12B schematically shows providing a resin composition on the base layer W-BS to form a preliminary resin layer P-RL (S200).

Referring to FIG. 12B, the resin composition may be provided on at least one surface of the base layer W-BS. The resin composition may be provided on one surface of the base layer W-BS in which the concave portion HP is defined. As shown in FIG. 12B, the resin composition may be provided on the first base surface BS-F1 of the base layer W-BS. The resin composition may be provided to fill the concave portion HP. The resin composition may be provided to entirely fill the concave portion HP.

As shown in FIG. 12B, the preliminary resin layer P-RL may overlap a first non-folded portion W-NFP1, a folding portion W-FP, and a second non-folded portion W-NFP2 of the base layer W-BS when viewed on a plane. However, the embodiment is not limited thereto, and the range in which the preliminary resin layer P-RL is provided may be appropriately altered depending on the type of a resin, the thickness and shape of a desired resin layer RL. For example, unlike what is shown in FIG. 12B, the preliminary resin layer P-RL may overlap the folding portion W-FP and may not overlap the first non-folding portion W-NFP1 and the second non-folding portion W-NFP2.

The resin composition may include the siloxane oligomer and the first organic compound previously described. In addition, the resin composition may further include a second organic compound in addition to the siloxane oligomer and the first organic compound. Hereinafter, a case in which the resin composition includes the siloxane oligomer, the first organic compound, and the second organic compound will be described as an example.

The resin composition may include at least one initiator. In an embodiment, the initiator included in the resin composition may be a photo-initiator activated by light in the ultraviolet region. The photo-initiator may be a photo-initiator activated by UV light having a central wavelength of about 100 nm to about 400 nm. When the resin composition includes a plurality of photo-initiators, different photo-initiators may be activated by UV light of different central wavelength ranges. Herein, the central wavelength indicates a wavelength representing a maximum intensity value of a light emission peak in the light emission spectrum of a light source. However, the embodiment of the disclosure is not limited thereto, and the resin composition may include a thermal initiator.

The photo-initiator may be any one selected from 2,2-dimethoxy-1,2-diphenylethan-1-one, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-one.

In addition, the photo-initiator may be any one selected from 2-methyl-1 [4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, 2,4,6-trimethylbenzoyl-diphenyl phosphinate, bis(2,4,6-trimethylbenzoyl)-phenylphosphineoxide, [1-(4-phenylsulfanylbenzoyl)heptylideneamino]benzoate, [1-[9-ethyl-6-(2-methylbenzoyl) carbazol-3-yl]ethylideneamino]acetate, and bis(2,4-cyclopentadienyl)bis [2,6-difluoro-3-(1-pyrryl)phenyl] titanium (IV). However, the embodiment of the disclosure is not limited thereto.

The resin composition may further include an additive as needed. The additive may be appropriately selected from general additives known in the art to control the physical properties required for an adhesive composition. For example, the additive may be a light stabilizer, a crosslinking agent, an antioxidant, a chain transfer agent, a photo-sensitizer, a polymerization inhibitor, a leveling agent, a surfactant, an adhesion imparting agent, a plasticizer, a UV absorbent, a storage stabilizer, an antistatic agent, an inorganic filler, a pigment, a dye, and the like, but is not limited to thereto. The additive may be used alone or in combination of two or more.

The resin composition may be provided in various ways. For example, the resin composition may be provided through spin-coating, slot-die, ink-jet printing, spray coating, or the like.

FIG. 12C is a view enlarging a resin composition included in a preliminary resin layer P-RL. The resin composition included in the preliminary resin layer P-RL may be in a pre-cured state. The siloxane oligomer, the first organic compound, and the second organic compound included in the resin composition in a pre-cured state may be provided in a dispersed state, separated within the resin composition.

Referring to FIG. 12C, a resin composition may include a plurality of cores CO including a siloxane oligomer, and a first organic compound OL1 and a second organic compound OL2. The second organic compound OL2 may be provided in the resin composition together with the first organic compound OL1 to form a bridge BG connecting the cores CO through a subsequent curing process.

The plurality of cores CO may include a siloxane oligomer. Each of the cores CO may include a first portion S1 including a siloxane unit, and a second portion S2 connected to the first portion S1 and including a polymerizable functional group. The first portion S1 may be a portion including a siloxane unit represented by SiO_{3/2}. The second portion S2 may be a substituent connected to a silicon atom of the first portion S1 and including a polymerizable functional group at a terminal. The plurality of cores CO may not form bonds with adjacent cores CO before curing.

FIGS. 12D to 12F schematically show providing heat or light to a preliminary resin layer P-RL to form a resin layer (S300). In FIGS. 12D to 12F, light is provided to the preliminary resin layer P-RL to form a resin layer RL, but the embodiment is not limited thereto.

Referring to FIGS. 12D and 12E, light LT may be provided to the preliminary resin layer P-RL coated with a resin composition to a uniform thickness. In an embodiment, the light LT may be ultraviolet light, but is not limited thereto. The light LT for curing the resin composition may be provided to the preliminary resin layer P-RL. The preliminary resin layer P-RL may be polymerized and cured by the provided light LT to form the resin layer RL. The light LT emitted may be in an amount of light that completely cures the resin composition.

FIG. 12F is a view enlarging a polymer compound included in a resin layer RL after curing.

The providing of heat or light to the preliminary resin layer P-RL may include combining a siloxane oligomer, a first organic compound, and a second organic compound included in the preliminary resin layer P-RL through a polymerization reaction. The cured resin layer RL may include a polymer compound obtained through a polymerization reaction of the siloxane oligomer, the first organic compound, and the second organic compound.

As shown in FIG. 12F, the polymer compound included in the resin layer RL may include a plurality of cores CO including a siloxane oligomer, and a plurality of linkages BG disposed between the plurality of cores CO and connecting the plurality of cores CO. The plurality of linkages BG may be formed as a condensate of the first organic compound OL1 (see FIG. 12C) and the second organic compound OL2 (see FIG. 12C). The plurality of linkages BG may be composed of the first organic compound OL1 (see FIG. 12C) and the second organic compound OL2 (see FIG. 12C). Through the curing process, each of the plurality of cores CO may form a bond with another adjacent core CO. The linkages BG may connect adjacent cores CO through a covalent bond. The polymer compound may include a bonding portion HB in which adjacent linkages BG are bonded through hydrogen bonding. The linkages BG, as previously described through FIG. 9B, may form hydrogen bonds through hydrogen bonding functional groups included in the first organic compound.

A window manufactured through the steps of FIGS. 12A to 12F may be applied to the electronic device ED previously described. A window manufactured through the steps of FIGS. 12A to 12F may be attached onto the display module DM. A window manufactured through the steps of FIGS. 12A to 12F may be formed in a separate process and provided onto the display module DM. However, the embodiment of the disclosure is not limited thereto, and the window WM may be formed on the display panel DP through a continuous process. When the window WM is provided on the display module DM and the first base surface BS-F1 in which the concave portion HP is defined is disposed closer to the display module DM (see FIG. 10A) than the second base surface BS-F2 is, the manufactured electronic device ED (see FIG. 10A) may have the structure of FIG. 10A. In addition, when the window WM is provided on the display module DM and the second base surface BS-F2 of the base layer W-BS is disposed closer to the display module DM (see FIG. 10B) than the first base surface BS-F1 in which the concave portion HP is defined, the manufactured electronic device ED (see FIG. 10B) may have the structure of FIG. 10B.

The resin layer RL according to an embodiment includes a polymer compound derived from a resin composition including a siloxane oligomer and a first organic compound, and may thus exhibit excellent self-restoring characteristics, excellent mechanical durability, and excellent optical properties together.

According to an embodiment of the disclosure, a window includes a resin layer derived from a resin composition including a siloxane oligomer and a first organic compound having a ureidopyrimidone unit, and may thus exhibit excellent self-restoring characteristics while also exhibiting excellent optical properties and excellent durability. Accordingly, an electronic device including the window may exhibit improved display quality and reliability.

The description has been made reference to embodiments of the disclosure, but those skilled or of ordinary skill in the art may understand that various modifications and changes may be made to the disclosure insofar as such modifications and changes do not depart from the spirit and technical scope of the disclosure set forth in the claims to be described later. Therefore, the technical scope of the disclosure is not to be limited to the contents stated in the detailed description of the specification, but should be determined by the claims.

What is claimed is:

1. A window comprising a first non-folding portion, a second non-folding portion, and a folding portion disposed between the first non-folding portion and the second non-folding portion,
the window including:
a base layer; and
a resin layer disposed on the base layer, wherein the resin layer comprises a polymer compound derived from a resin composition including a siloxane oligomer and a first organic compound represented by Formula 1: 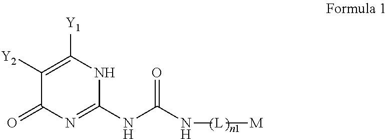
wherein in Formula 1,
Y₁ and Y₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
M is a substituted or unsubstituted (meth)acrylate group, a substituted or unsubstituted vinyl group, a substituted or unsubstituted epoxy group, or a substituted or unsubstituted oxetanyl group,
each L is independently a direct linkage, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
n1 is an integer of 1 to 20.

2. The window of claim 1, wherein the siloxane oligomer comprises a silsesquioxane compound having at least one polymerizable functional group.

3. The window of claim 1, wherein the siloxane oligomer comprises a silsesquioxane compound having at least one (meth)acrylate group.

4. The window of claim 1, wherein the resin composition further comprises a second organic compound different from the first organic compound, and the second organic compound comprises a polymerizable monomer.

5. The window of claim 3, wherein the second organic compound is represented by Formula 2: 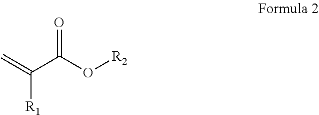
wherein,
R₁ is a hydrogen atom or a substituted or unsubstituted alkyl group having 1 to 20 carbon atoms, and
R₂ is a substituted or unsubstituted alkyl group having 1 to 20 carbon atoms.

6. The window of claim 4, wherein the polymer compound is formed through a polymerization reaction of the siloxane oligomer, the first organic compound, and the second organic compound.

7. The window of claim 1, wherein the polymer compound comprises a plurality of cores having the siloxane oligomer, and a plurality of linkages connecting the plurality of cores,
the plurality of linkages include the first organic compound, and adjacent linkages of the plurality of linkages can connect through hydrogen bonds.

8. The window of claim 1, wherein the resin layer has a transmittance of about 90% or greater for light having a central wavelength of about 400 nm to about 700 nm.

9. The window of claim 1, wherein the resin layer has a yellow index of about 2 or less.

10. The window of claim 1,
wherein the folding portion of the base layer comprises a concave portion, and the resin layer is disposed within the concave portion.

11. The window of claim 10, wherein the resin layer fills the concave portion and overlaps the first non-folding portion, the second non-folding portion, and the folding portion.

12. The window of claim 1, wherein the base layer is a glass substrate.

13. An electronic device comprising:
a display module including a folding display portion that is foldable with respect to a folding axis extending in one direction, and a first non-folding display portion and a second non-folding display portion that are spaced apart with the folding display portion therebetween; and
a window disposed on the display module and including a folding portion corresponding to the folding display portion, and a first non-folding portion and a second non-folding portion respectively corresponding to the first non-folding display portion and the second non-folding display portion,
wherein the window includes:
a base layer; and
a resin layer disposed on the base layer, wherein the resin layer comprises a polymer compound derived from a resin composition including a siloxane oligomer and a first organic compound represented by Formula 1: 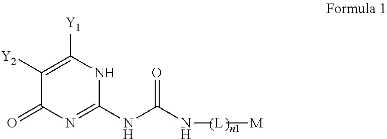
wherein in Formula 1,
Y₁ and Y₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
M is a substituted or unsubstituted (meth)acrylate group, a substituted or unsubstituted vinyl group, a substituted or unsubstituted epoxy group, or a substituted or unsubstituted oxetanyl group,
each L is independently a direct linkage, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
n1 is an integer of 1 to 20.

14. The electronic device of claim 13, wherein the folding portion of the base layer comprises a concave portion, and the resin layer is disposed within the concave portion.

15. The electronic device of claim 14, wherein the base layer comprises a first base surface having the concave portion, and a second base surface facing the first base surface, and
the first base surface is disposed adjacent to the display module.

16. The electronic device of claim 14, wherein the base layer comprises a first base surface having the concave portion, and a second base surface facing the first base surface, and
the second base surface is disposed adjacent to the display module.

17. The electronic device of claim 13, further comprising at least one of a power module, a processor, or a memory.

18. A method for manufacturing a window, the method comprising:
preparing a base layer including a folding region, and a first non-folding region and a second non-folding region that are spaced apart with the folding region therebetween;
applying a resin composition including a siloxane oligomer and a first organic compound represented by Formula 1 onto one surface of the base layer to form a preliminary resin layer; and
providing heat or light to the preliminary resin layer to form a resin layer, 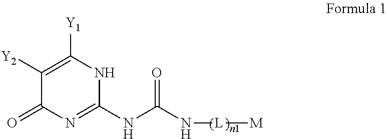
wherein in Formula 1,
Y₁ and Y₂ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
M is a substituted or unsubstituted (meth)acrylate group, a substituted or unsubstituted vinyl group, a substituted or unsubstituted epoxy group, or a substituted or unsubstituted oxetanyl group,
each L is independently a direct linkage, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
n1 is an integer of 1 to 20.

19. The method of claim 18, wherein the folding portion of the base layer comprises a concave portion, and the resin layer is disposed within the concave portion.

20. The method of claim 18, wherein the providing of heat or ultraviolet light to the preliminary resin layer polymerizes the siloxane oligomer with the first organic compound.
